(19) United States
(12) Patent Application Publication
(10) Pub. No.: US 2026/0020473 A1
(43) Pub. Date: Jan. 15, 2026

(54) ORGANIC LIGHT-EMITTING ELEMENT, AND DISPLAY APPARATUS AND ELECTRONIC APPARATUS EACH INCLUDING THE SAME

(71) Applicant: Samsung Display Co., Ltd., Yongin-si (KR)

(72) Inventors: Dongchan Kim, Yongin-si (KR); Seongkeun Kim, Yongin-si (KR); Wonjong Kim, Yongin-si (KR); Sungsoo Bae, Yongin-si (KR); Byeongwook Yoo, Yongin-si (KR); Daewoong Lee, Yongin-si (KR); Byungseok Lee, Yongin-si (KR); Youngeun Choi, Yongin-si (KR); Jiyong Choi, Yongin-si (KR); Hyewon Choi, Yongin-si (KR)

(21) Appl. No.: 19/261,845

(22) Filed: Jul. 7, 2025

(30) Foreign Application Priority Data
Jul. 9, 2024 (KR) 10-2024-0090670

(51) Int. Cl. H10K 59/80; H10K 50/13; H10K 50/82

(52) U.S. Cl. CPC H10K 59/8052; H10K 50/131; H10K 50/82

(57) ABSTRACT

An organic light-emitting element includes a first electrode, a hole injection layer on the first electrode, a hole transport layer on the hole injection layer, an emission layer on the hole transport layer and including an organic material, an electron transport layer on the emission layer, and a second electrode directly on the electron transport layer and including a conductive material other than alkali metal and about 3 vol % to about 30 vol % of an alkali metal based on a total volume of 100 vol % of the second electrode.

### CROSS-REFERENCE TO RELATED APPLICATION

The present application claims priority to and the benefit of Korean Patent Application No. 10-2024-0090670, filed on Jul. 9, 2024, in the Korean Intellectual Property Office, the entire disclosure of which is incorporated herein by reference.

### BACKGROUND

### 1. Field

One or more embodiments of the present disclosure relate to an organic light-emitting element, and a display apparatus and an electronic apparatus each including the same, for example, to an organic light-emitting element with a simplified structure and improved efficiency, and a display apparatus and an electronic apparatus each including the same.

### 2. Description of the Related Art

Among display apparatuses, organic light-emitting display apparatuses have gained attention as the next generation of display apparatuses due to their relatively wide viewing angle, high contrast, and fast response speed.

Generally, an organic light-emitting display apparatus includes thin-film transistors and light-emitting diodes (that is, organic light-emitting diodes/elements) arranged on a substrate, wherein the light-emitting diodes/elements emit light spontaneously under a driving voltage. Organic light-emitting display apparatuses have been broadly used as displays units of miniaturized products such as mobile phones or large-scale products such as televisions.

A light-emitting diode/element may have a structure in which a first electrode (e.g., an anode) is arranged on a substrate, followed sequentially by a hole transport region, an emission layer, an electron transport region, and a second electrode (e.g., a cathode). Holes injected from the first electrode move to the emission layer through the hole transport region, while electrons injected from the second electrode move to the emission layer through the electron transport region. These carriers, namely the holes and electrons, recombine in the emission layer to create excitons. When these excitons transition and decay from an excited state to a ground state, light is emitted.

### SUMMARY

Desired characteristics of a material for a second electrode (e.g., a cathode) of a light-emitting element include a low light absorption rate, a low driving resistance, and a high environment reliability.

One or more aspects of embodiments of the present disclosure are directed toward an organic light-emitting element with a simplified structure and an improved efficiency by including such a second electrode or cathode.

One or more aspects of embodiments of the present disclosure are directed toward a display apparatus and an electronic apparatus each including the organic light-emitting element.

Additional aspects will be set forth in part in the description which follows and, in part, will be apparent from the description, or may be learned by practice of the presented embodiments of the disclosure.

According to one or more embodiments of the present disclosure, an organic light-emitting element includes a first electrode, a hole injection layer on (e.g., arranged on) the first electrode, a hole transport layer on (e.g., arranged) on the hole injection layer, an emission layer on (e.g., arranged on) the hole transport layer and including an organic material, an electron transport layer on (e.g., arranged on) the emission layer, and a second electrode directly on (e.g., arranged on) the electron transport layer and including a conductive material other than alkali metal and about 3 vol % to about 30 vol % of an alkali metal based on a total volume of 100 vol % of the second electrode.

In one or more embodiments, the alkali metal of the second electrode may include about 0.5 wt % to about 1.5 wt % of lithium (Li) based on a total weight of 100 wt % of the second electrode.

In one or more embodiments, the alkali metal of the second electrode may include about 0.27 wt % to about 2.69 wt % of sodium (Na) based on a total weight of 100 wt % of the second electrode.

A thickness of the second electrode may be about 50 angstroms (Å) to about 200 Å.

A work function of the alkali metal of the second electrode may be about 2.3 eV to about 2.9 eV.

A light absorption rate k of the alkali metal of the second electrode may be about 1.79 to about 2.03 with respect to light having a wavelength of about 450 nm.

The emission layer may include a stack of two or more layers.

In one or more embodiments, a proportion of the alkali metal within the second electrode may gradually increase from a central portion of a cross-section of the second electrode toward the electron transport layer.

In one or more embodiments, a proportion of the alkali metal within the second electrode may gradually increase in a direction away from the central portion of the cross-section of the second electrode.

According to one or more embodiments of the present disclosure, a display apparatus includes: a substrate; a circuit layer on (e.g., arranged over) the substrate and including a unit circuit and an insulating layer, the unit circuit including a thin-film transistor and a storage capacitor; an organic light-emitting element on (e.g., arranged on) the circuit layer and electrically connected to the unit circuit; and an encapsulation layer arranged on the organic light-emitting element and sealing the organic light-emitting emitting element, wherein the organic light-emitting element includes a first electrode, a hole injection layer on (e.g., arranged on) the first electrode, a hole transport layer on (e.g., arranged on) the hole injection layer, an emission layer on (e.g., arranged on) the hole transport layer and including an organic material, an electron transport layer on (e.g., arranged) on the emission layer, and a second electrode directly on (e.g., arranged on) the electron transport layer and including a conductive material other than alkali metal and about 3 vol % to about 30 vol % of an alkali metal based on a total volume of 100 vol % of the second electrode.

In one or more embodiments, the alkali metal of the second electrode may include about 0.5 wt % to about 1.5 wt % of lithium (Li) based on a total weight of 100 wt % of the second electrode.

In one or more embodiments, the alkali metal of the second electrode may include about 0.27 wt % to about 2.69 wt % of sodium (Na) based on a total weight of 100 wt % of the second electrode.

A thickness of the second electrode may be about 50 Å to about 200 Å.

A work function of the alkali metal of the second electrode may be about 2.3 eV to about 2.9 eV.

The emission layer may include two or more layers.

A proportion of the alkali metal within the second electrode may gradually increase from a central portion of a cross-section of the second electrode toward the electron transport layer.

The display apparatus may further include a capping layer on (e.g., arranged on) the second electrode, and a proportion of the alkali metal within the second electrode may gradually increase from the central portion of the cross-section of the second electrode toward the capping layer.

The substrate may include a display area and a peripheral area outside the display area, the organic light-emitting element may be provided in plurality in the display area, the second electrode may be integral with respect to the plurality of organic light-emitting elements over an entire surface of the display area, and a proportion of the alkali metal within the second electrode may be lowest in a portion of the second electrode corresponding to a central portion of the display area, and may increase toward a portion of the second electrode corresponding to an edge of the display area.

The organic light-emitting element may include a first organic light-emitting element arranged in a central portion of the display area, and a second organic light-emitting element arranged at (e.g., in or in proximity to) an edge of the display area, the second electrode may be integrally arranged over the first organic light-emitting element and the second organic light-emitting element and may include a first portion of (e.g., in) the first organic light-emitting element and a second portion of (e.g., in) the second organic light-emitting element, and in the first organic light-emitting element, a proportion of the alkali metal within the first portion of the second electrode may gradually increase in a direction away from a central portion of a cross-section of the first portion of the second electrode.

In the second organic light-emitting element, a proportion of the alkali metal within the second portion of the second electrode may be constant.

According to one or more embodiments of the present disclosure, an electronic apparatus includes a processor and a display apparatus controlled or selected by the processor, wherein the display apparatus includes: a substrate; a circuit layer on (e.g., arranged over) the substrate and including a unit circuit and an insulating layer, the unit circuit including a thin-film transistor and a storage capacitor; an organic light-emitting element on (e.g., arranged on) the circuit layer and electrically connected to the unit circuit; and an encapsulation layer on (e.g., arranged on) the organic light-emitting element and sealing the organic light-emitting element, wherein the organic light-emitting element includes a first electrode, a hole injection layer on (e.g., arranged on) the first electrode, a hole transport layer on (e.g., arranged on) the hole injection layer, an emission layer on (e.g., arranged on) the hole transport layer and including an organic material, an electron transport layer on (e.g., arranged on) the emission layer, and a second electrode directly on (e.g., arranged on) the electron transport layer and including a conductive material other than alkali metal and about 3 vol % to about 30 vol % of an alkali metal based on a total volume of 100 vol % of the second electrode.

In one or more embodiments, the alkali metal of the second electrode may include about 0.5 wt % to about 1.5 wt % of lithium (Li) based on a total weight of 100 wt % of the second electrode.

In one or more embodiments, the alkali metal of the second electrode may include about 0.27 wt % to about 2.69 wt % of sodium (Na) based on a total weight of 100 wt % of the second electrode.

These and/or other aspects will become apparent and more readily appreciated from the following detailed description of one or more embodiments, the accompanying drawings, and claims.

These general and specific aspects may be implemented by using a system, a method, a computer program, and/or a (e.g., any suitable) combination of a certain system, method, and computer program.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1 is a schematic cross-sectional view of a structure of an organic light-emitting element according to one or more embodiments of the present disclosure;

FIG. 2 is a schematic cross-sectional view of a structure of an organic light-emitting element according to one or more embodiments of the present disclosure;

FIGS. 3 and 4 are each a schematic cross-sectional view of a stack structure of an organic light-emitting element according to one or more embodiments of the present disclosure;

FIGS. 5A and 5B are each a schematic plan view showing a display apparatus according to one or more embodiments of the present disclosure;

FIGS. 6A and 6B are each an equivalent circuit diagram of a pixel of a display apparatus according to one or more embodiments of the present disclosure;

FIG. 7 is a schematic cross-sectional view of a portion of a display apparatus according to one or more embodiments of the present disclosure;

FIGS. 8 and 9 are each a schematic cross-sectional view of a second electrode according to one or more embodiments of the present disclosure;

FIGS. 10 and 11 are graphs showing an amount of change in brightness and an amount of change in a driving voltage over time, respectively, of embodiments described in Table 3;

FIG. 12 is a block diagram of an electronic apparatus according to one or more embodiments of the present disclosure; and

FIG. 13 is a schematic view of electronic apparatuses according to one or more suitable embodiments of the present disclosure.

### DETAILED DESCRIPTION

Reference will now be made in more detail to one or more embodiments, examples of which are illustrated in the accompanying drawings, wherein like reference numerals refer to like elements throughout the disclosure, and duplicative descriptions thereof may not be provided for conciseness. In this regard, the presented embodiments may have different forms and should not be construed as being limited to the descriptions set forth herein. Accordingly, one or more embodiments are merely described in more detail, by referring to the drawings, to explain aspects of the present disclosure. As used herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

As the disclosure allows for one or more suitable changes and numerous embodiments, certain embodiments will be illustrated in the drawings and described in the written description. Effects and features of the disclosure, and methods for achieving them will be clarified with reference to one or more embodiments described in more detail with reference to the drawings. However, the disclosure is not limited to the following embodiments and may be embodied in one or more suitable forms.

Hereinafter, embodiments will be described with reference to the accompanying drawings, wherein like reference numerals refer to like elements throughout and a repeated description thereof may not be provided for conciseness.

While such terms as “first” and “second” may be used to describe one or more suitable components, such components must not be limited to the above terms. The above terms are merely used to distinguish one component from another. Thus, a first element described could also be termed as a second or third element without departing from the spirit and scope of the disclosure.

The singular forms “a,” “an,” “one,” and “the” as used herein are intended to include the plural forms as well unless the context clearly indicates otherwise.

It will be understood that the terms “comprise(s)/comprising,” “include(s)/including,” and/or “have/has/having” as used herein specify the presence of stated features or components but do not preclude the addition of one or more other features or components. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. Further, the use of “may” when describing embodiments of the present disclosure refers to “one or more embodiments of the present disclosure.

It will be further understood that, if (e.g., when) a layer, region, or component is referred to as being “on” another layer, region, or component, it may be directly or indirectly on the other layer, region, or component. For example, for example, one or more intervening layers, regions, or components may be present therebetween. In contrast, if (e.g., when) an element is referred to as being “directly on” another element, there are no intervening element present therebetween.

It will be understood that if (e.g., when) a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that if (e.g., when) a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

In the present disclosure, “A and/or B” refers to A or B, or A and B. In the present disclosure, “at least one of A and B” refers to A or B, or A and B.

The x-axis, the y-axis, and the z-axis as used herein are not limited to three axes of the cubic coordinate system, and may be interpreted in a broader sense. For example, the x-axis, the y-axis, and the z-axis may be normal (e.g., perpendicular) to one another, or may represent different orientations that are not normal (e.g., perpendicular) to one another.

In the case where a certain embodiment may be implemented differently, a specific process order may be performed in the order different from the described order. For example, two processes successively described may be concurrently (e.g., simultaneously) performed substantially and performed in the opposite order.

Also, sizes of elements in the drawings may be exaggerated or reduced for convenience of explanation. For example, the size and thickness of each element shown in the drawings are illustratively represented for convenience of description, and thus, the disclosure is not necessarily limited thereto.

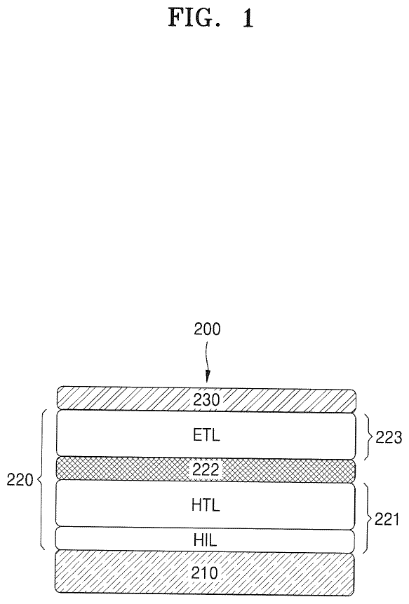

FIG. 1 is a schematic cross-sectional view of a structure of an organic light-emitting element according to one or more embodiments of the present disclosure.

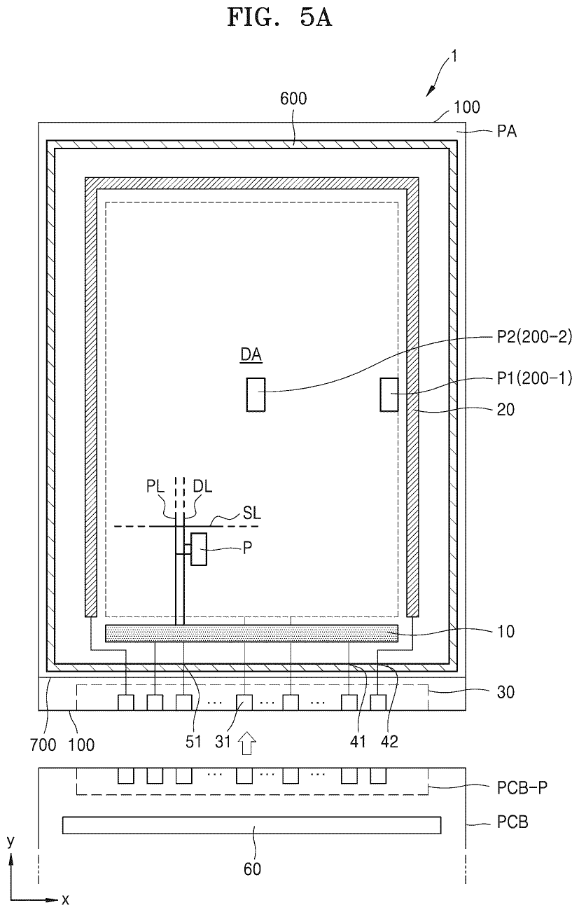

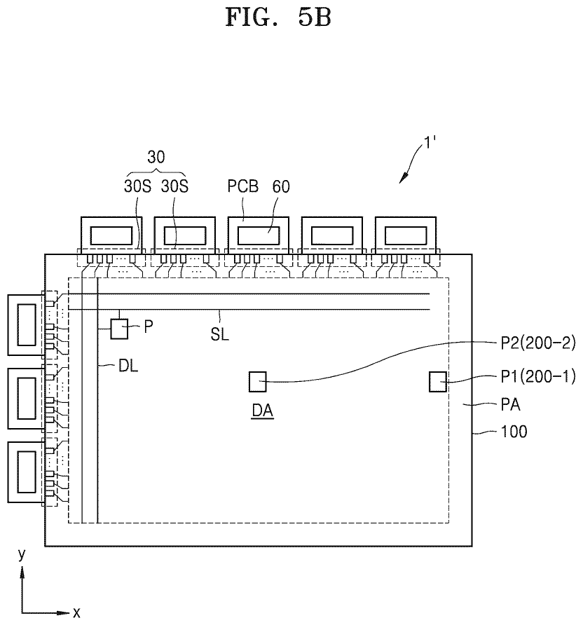

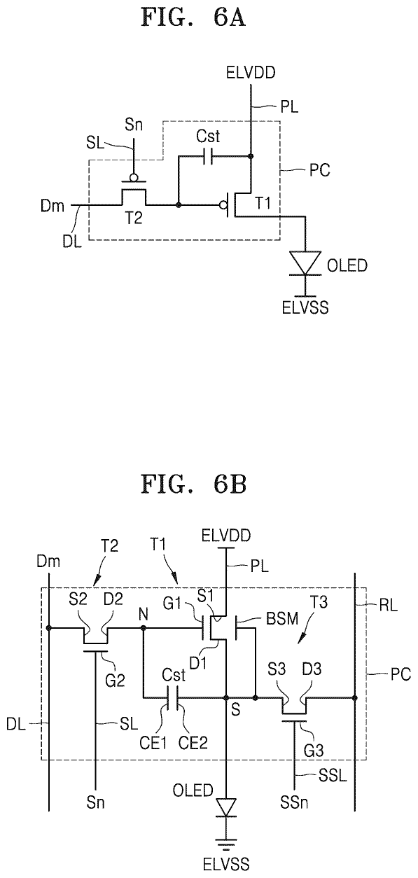

Referring to FIG. 1, an organic light-emitting element 200 is an organic light-emitting diode (OLED) that may be included in each pixel P (see FIG. 5A or 5B). The organic light-emitting element 200 may be electrically connected to a pixel circuit PC (see FIG. 6A or 6B) and may control a degree of light emission by receiving power and signals through the pixel circuit PC.

The organic light-emitting element 200 may include a first electrode 210, a second electrode 230, and an intermediate layer 220 between (e.g., arranged between) the first electrode 210 and the second electrode 230.

The first electrode 210 is a pixel electrode (that is, an anode) and may be patterned for each organic light-emitting element 200. In one or more embodiments, the first electrode 210 of the organic light-emitting element 200 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In one or more embodiments, the first electrode 210 may further include a layer on and/or under the reflective layer, the layer including ITO, IZO, ZnO, and/or In₂O₃. In one or more embodiments, the first electrode 210 may include a single-layered structure including (e.g., consisting of) a single layer, or a multi-layered structure including a plurality of layers. For example, in one or more embodiments, the first electrode 210 may have a three-layered structure of ITO/Ag/ITO.

A first common layer 221 may be arranged on the first electrode 210. The first common layer 221 may serve as a hole transport region. The first common layer 221 may include at least one layer selected from among a hole injection layer (HIL), a hole transport layer (HTL), an emission auxiliary layer, and an electron blocking layer. Thicknesses of the HIL, the HTL, the emission auxiliary layer, and the electron blocking layer may be set independently from one another.

As an example, although the hole transport region may have a single-layered structure including a single layer including a plurality of different materials, or a multi-layered structure including a hole injection layer/a hole transport layer, a hole injection layer/a hole transport layer/an emission auxiliary layer, a hole injection layer/an emission auxiliary layer, a hole transport layer/an emission auxiliary layer, or a hole injection layer/a hole transport layer/an electron blocking layer, each constituent layer sequentially stacked from the first electrode, the hole transport region is not limited thereto.

In one or more embodiments, it is shown in FIG. 1 that the organic light-emitting element 200 includes an HIL and an HTL as the hole transport region. The HIL may be arranged to be adjacent to the first electrode 210, and the HTL may be arranged on the HIL.

The HIL may facilitate hole injection. Although, in one or more embodiments, the HIL may include at least one of HATCN(dipyrazino[2,3-f: 2′,3′-h] quinoxaline-2,3,6,7,10,11-hexacarbonitrile), CuPc(cupper phthalocyanine), PEDOT(poly(3,4)-ethylenedioxythiophene), PANI(polyaniline), or NPD(N, N-dinaphthyl-N, N′-diphenylbenzidine), embodiments of the present disclosure are not limited thereto.

The HTL may include, as a host of the HTL, a triphenylamine derivative having high hole mobility and high stability such as TCTA(4,4′,4″-tris(N-carbazolyl)triphenylamine), TPD(N, N′-diphenyl-N,N′-bis(3-methylphenyl)-1,1′-bi-phenyl-4,4′-diamine), and/or NPB(N,N′-di(naphthalen-1-yl)-N,N′-diphenyl-benzidine). Although the HTL is shown as a single layer in FIG. 1, the HTL may have a multi-layered structure. The HTL may have a multi-layered structure of two or more layers including different materials selected from among the above materials. For example, in one or more embodiments, the HTL may include a double layer including NPB and TCTA.

An emission layer 222 may be arranged on the first common layer 221. The emission layer 222 may include an organic material emitting red, blue, or green light. For example, in embodiments in which the emission layer 222 is to emit red light, the emission layer 222 may be formed by using, for example, a red dopant (i.e., dopant that emits red light) as a preset host material. In one or more embodiments, in the case where the emission layer 222 emits green light, the emission layer 222 may be formed by using, for example, a green dopant (i.e., dopant that emits green light) as a preset host material. In one or more embodiments, in the case where the emission layer 222 emits blue light, the emission layer 222 may be formed by using, for example, a blue dopant (i.e., dopant that emits blue light) as a preset host material.

A second common layer 223 may be arranged on the emission layer 222. The second common layer 223 may serve as an electron transport region. The second common layer 223 may include at least one of a buffer layer, a hole blocking layer, an electron adjusting layer, or an electron transport layer (ETL). Thicknesses of the buffer layer, the hole blocking layer, the electron adjusting layer, and the ETL may be set independently from one another.

As an example, although the electron transport region may have a single-layered structure including a single layer including a plurality of different materials, or a structure including an electron transport layer, a hole blocking layer/an electron transport layer, an electron adjusting layer/an electron transport layer, or a buffer layer/an electron transport layer, each constituent layer sequentially stacked from the emission layer, the electron transport region is not limited thereto.

In one or more embodiments, it is shown in FIG. 1 that the organic light-emitting element 200 includes an ETL as the electron transport region. The ETL may be arranged on the emission layer 222, and the second electrode 230 may be arranged on the ETL. For example, in one or more embodiments, an electron injection layer (EIL) is not arranged between the ETL and the second electrode 230, and the ETL may be arranged to be in direct face-contact with the second electrode 230.

The ETL facilitates electron transport. Although, in one or more embodiments, the ETL may include at least one of Alq3(tris(8-hydroxyquinolinato)aluminum), PBD(2-(4-biphenyl)-5-(4-tert-butylphenyl)-1,3,4-oxadiazole), TAZ(3-(4-biphenyl)-4-phenyl-5-tert-butylphenyl-1,2,4-triazole), spiro-PBD, BAlq(bis(2-methyl-8-quinolinolato-N1,O8)-(1,1′-biphenyl-4-olato)aluminum), Liq(lithium quinolinolate), BMB-3T(5,5′-bis(dimesitylboryl)-2,2′:5′,2′-terthiophene), PF-6P, TPBI(1,3,5-tris(1-phenyl-1H-benzo[d]imidazol-2-yl)benzene), COT, or SAlq(bis(2-methyl 8-hydroxyquinoline) (triphenyl siloxy) aluminum), embodiments of the present disclosure are not limited thereto.

Although it is shown in FIG. 1 that the organic light-emitting element 200 includes an HIL, an HTL, and an ETL, embodiments of the disclosure are not necessarily limited thereto. In one or more embodiments, at least one of an HIL, an HTL, or an ETL may not be provided.

In one or more embodiments, remaining layers other than the emission layer 222, for example, the HIL, the HTL, and the ETL may be integrally provided over a plurality of organic light-emitting elements 200.

The second electrode 230 is an opposite electrode (that is, a cathode) and may be integrally provided over a plurality of organic light-emitting elements 200. The second electrode 230 may include a conductive material having a low work function. For example, in one or more embodiments, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In one or more embodiments, the second electrode 230 may further include a layer on the (semi) transparent layer, the layer including ITO, IZO, ZnO, and/or In₂O₃.

In one or more embodiments, the organic light-emitting element 200 of FIG. may further include an alkali metal in addition to the above-described conductive material. The alkali metal refers to a metal in Group 1 of the periodic table, and may include, for example, lithium (Li) or sodium (Na). Because the second electrode 230 is formed to include the alkali metal, the second electrode 230 may serve as an electron injection layer, and thus, the electron injection layer does not need to be separately formed within the organic light-emitting element 200, and the element structure may be simplified. In addition, because the alkali metal has a low light absorption rate compared to other metal material, particularly, a reflective metal (e.g., Mg and/or the like), a light absorption rate of the entire second electrode 230 may be reduced through this, and thus, the element efficiency may be improved.

In one or more embodiments, about 3 vol % to about 30 vol % of alkali metal may be included in the second electrode 230, based on a total volume of 100 vol % of the second electrode 230. When less than 3 vol % of alkali metal is included, an electron injection effect is insufficient, and if (e.g., when) more than 30 vol % of alkali metal is included, the proportion of the conductive material is reduced, and electrical characteristics deteriorate.

In one or more embodiments, a work function of the alkali metal included in the second electrode 230 may be about 2.3 eV to about 2.9 eV. In addition, a light absorption rate K of the alkali metal included in the second electrode 230 may be about 1.79 to about 2.03 with respect to light having a wavelength of about 450 nm. In the embodiment in which the alkali metal satisfies the above-described physical property range, the characteristics of the organic light-emitting element 200 equal to or more improved than those of the related art may be obtained even without forming the EIL.

In one or more embodiments, the second electrode 230 may include lithium (Li), for example, in embodiments in which the second electrode 230 includes silver (Ag) as a conductive material, the second electrode 230 may include Ag and Li co-deposited. A thickness of the second electrode 230 including Li may be about 50 Å to about 200 Å. In the case where the thickness of the second electrode 230 is less than 50 Å, the element stability deteriorates and a resistance increases, and in the case where the thickness of the second electrode 230 exceeds 200 Å, a light efficiency may deteriorate.

In one or more embodiments, about 0.5 wt % to about 1.5 wt % of Li, based on a total weight of 100 wt % of the second electrode 230, may be included in the second electrode 230. In other words, about 10 vol % to about 30 vol % of Li, based on a total volume of 100 vol % of the second electrode 230, may be included in the second electrode 230. In the case where the content (e.g., amount) of Li is less than 0.5 wt %, a light efficiency and an element lifespan are reduced, and in the case where the content (e.g., amount) of Li exceeds 1.5 wt %, electrical characteristics may deteriorate.

In one or more embodiments, the second electrode 230 may include sodium (Na), for example, in embodiments in which the second electrode 230 includes silver (Ag) as a conductive material, the second electrode 230 may include Ag and Na co-deposited. A thickness of the second electrode 230 including Na may be about 50 Å to about 200 Å. In the case where the thickness of the second electrode 230 is less than 50 Å, the element stability deteriorates and a resistance increases, and in the case where the thickness of the second electrode 230 exceeds 200 Å, a light efficiency may deteriorate.

In one or more embodiments, about 0.27 wt % to about 2.69 wt % of Na, based on a total weight of 100 wt % of the second electrode 230, may be included in the second electrode 230. In other words, about 3 vol % to about 30 vol % of Na, based on a total volume of 100 vol % of the second electrode 230, may be included in the second electrode 230. In the case where the content (e.g., amount) of Na is less than 0.27 wt %, a light efficiency and an element lifespan are reduced, and in the case where the content (e.g., amount) of Na exceeds 2.69 wt %, electrical characteristics may deteriorate.

The second electrode 230 may be formed through deposition, for example, formed through thermal evaporation. The second electrode 230 may include a conductive material and an alkali metal co-deposited.

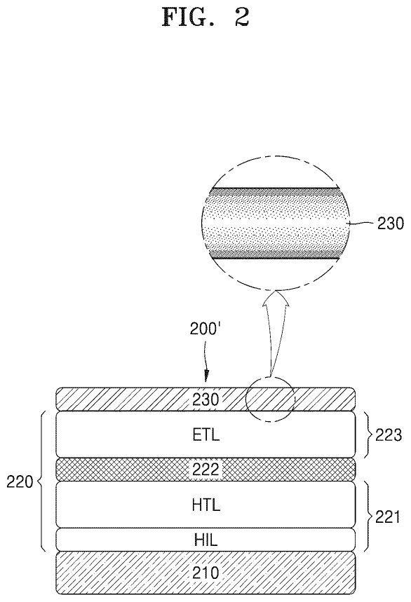

In one or more embodiments, when forming the second electrode 230, the conductive material and the alkali metal are formed in a co-deposited form, and a ratio of the alkali metal may be adjusted to control forming of a concentration gradient of the alkali metal within the second electrode 230. This is described in more detail with reference to FIG. 2.

FIG. 2 is a schematic cross-sectional view of a structure of an organic light-emitting element 200′ according to one or more embodiments of the present disclosure.

Referring to FIG. 2, the stack structure of the organic light-emitting element 200′ of FIG. 2 is substantially the same as that of FIG. 1 except is different in the structure of the second electrode 230.

In one or more embodiments, the second electrode 230 may further include an alkali metal in addition to the conductive material. In these embodiments, the alkali metal may be provided to have a concentration gradient within the second electrode 230. The proportion of the alkali metal within the second electrode 230 may gradually increase in a direction away from the central portion of the second electrode 230 in the cross-section of the second electrode 230. In the context of the present disclosure, “gradually increase” refers to that the increase in the proportion of alkali metal occurs slowly and steadily as the distance from the central portion of the cross-section increases, rather than suddenly or abruptly. This creates the concentration gradient where the concentration of alkali metal is lower at the center and progressively becomes higher towards the edges of the cross-section. For example, the proportion of the alkali metal within the second electrode 230 may be high toward (e.g., near) the ETL, and may be also high toward (e.g., near) the upper portion of the second electrode 230 which is the opposite side of the ETL. The proportion of the alkali metal within the second electrode 230 may be formed to be symmetrical with respect to the central portion of the cross-section of the second electrode 230. For example, the second electrode may include an alkali metal in addition to the conductive material. The alkali metal may have a concentration gradient within the second electrode, with its proportion gradually increasing away from the central portion of the electrode's cross-section. Specifically, the alkali metal concentration may be higher near the electron transport layer (ETL) and the upper portion of the second electrode, forming a symmetrical distribution with respect to the central portion of the cross-section.

For example, because the proportion of the alkali metal within the second electrode 230 is highest on a surface close to the ETL and becomes lower toward the central portion of the cross-section of the second electrode 230, the proportion of the conductive metal (e.g., Ag) may be higher in the central portion of the cross-section of the second electrode 230. For example, in one or more embodiments, the central portion of the cross-section of the second electrode 230 may not include (e.g., may exclude any of) the alkali metal or may include a small amount of the alkali metal, and most of the material may include (e.g., be) the conductive metal. As described above, the electrical resistance of the second electrode 230 may be effectively reduced by reducing the proportion of the alkali metal and increasing the proportion of the conductive metal in the central portion of the cross-section of the second electrode 230 such that the alkali metal has a concentration gradient within the second electrode 230, thereby allowing the conductive metal having a low work function to be relatively much included. For example, the central portion may exclude or contain only a small amount of alkali metal, primarily composed of conductive metal. This distribution reduces electrical resistance by increasing the conductive metal proportion in the central portion, allowing for a concentration gradient of alkali metal within the second electrode.

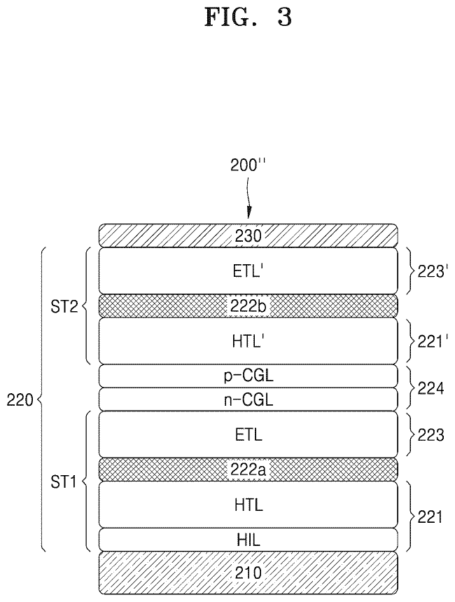

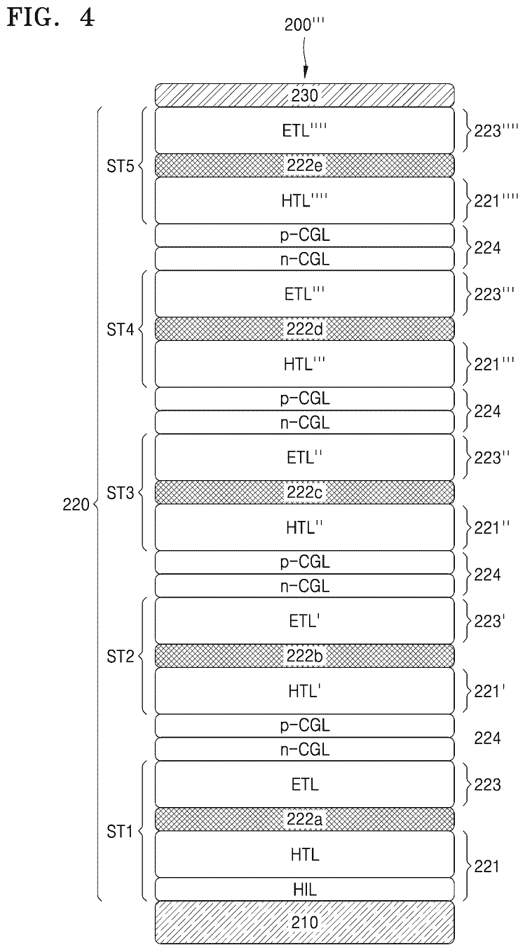

FIG. 3 and FIG. 4 are each a schematic cross-sectional view of a stack structure of an organic light-emitting elements 200″ and 200″ according to one or more embodiments of the present disclosure.

Referring to FIG. 3 and FIG. 4, the organic light-emitting elements 200″ and 200′″ are each an organic light-emitting diode (OLED), and may be independently included in a pixel P (see FIG. 5A or 5B). The organic light-emitting elements 200″ and 200″ may be independently electrically connected to the pixel circuit PC of FIG. 6A or 6B and may control a degree of light emission by receiving power and signals through the pixel circuit PC.

The organic light-emitting elements 200″ and 200″ of FIG. 3 or FIG. 4 may each include a tandem structure including a stack of m or more emitting units. (m is an integer equal to or greater than 2). (m−1) charge generation layers 224 may be respectively arranged between adjacent stacks.

Referring to FIG. 3, in one or more embodiments, the organic light-emitting elements 200″ may have a tandem structure including a stack of two or more emitting units. FIG. 3 shows the organic light-emitting elements 200″ including a first stack ST1 and a second stack ST2 totally including two emitting units. The first stack ST1 and the second stack ST2 may include a first emission layer 222a and a second emission layer 222b, respectively.

The charge generation layer 224 may be arranged between the first stack ST1 and the second stack ST2.

Referring to FIG. 4, in one or more embodiments, the organic light-emitting elements 200″ may have a tandem structure including a stack of five or more emitting units. FIG. 4 shows the organic light-emitting elements 200″ including a first stack ST1, a second stack ST2, a third stack ST3, a fourth stack ST4, and a fifth stack ST5 totally including five emitting units. The first emission layer 222a may be included in the first stack ST1, the second emission layer 222b may be included in the second stack ST2, a third emission layer 222c may be included in the third stack ST3, a fourth emission layer 222d may be included in the fourth stack ST4, and a fifth emission layer 222e may be included in the fifth stack ST5.

The first emission layer 222a to the fifth emission layer 222e may each independently include an organic material emitting red, blue, or green light. For example, the first emission layer 222a to the fifth emission layer 222e of the organic light-emitting elements 200″ according to one or more embodiments may be to emit blue light or green light. For example, in one or more embodiments, the first emission layer 222a and the second emission layer 222b may be to emit blue light, and the third emission layer 222c and the fifth emission layer 222e may be to emit green light.

The charge generation layers 224 may be respectively arranged between adjacent stacks selected from among the first stack ST1 to the fifth stack ST5.

The first stack ST1 to the fifth stack ST5 may respectively include first common layers 221, 221′, 221″, 221″, and 221″, and second common layers 223, 223′, 223″, 223″, and 223″ with the first to fifth emission layers 222a, 222b, 222c, 222d, and 222e therebetween.

In one or more embodiments, the first common layer 221 of the first stack ST1 may include an HIL and an HTL, and the second common layer 223 of the first stack ST1 may include an ETL. The first common layer 221′ of the second stack ST2 may include an HTL′, and the second common layer 223′ of the second stack ST2 may include an ETL′. The first common layer 221″ of the third stack ST3 may include an HTL″, and the second common layer 223″ of the third stack ST3 may include an ETL″. The first common layer 221″ of the fourth stack ST4 may include an HTL″, and the second common layer 223″ of the fourth stack ST4 may include an ETL″. The first common layer 221′″ of the fifth stack ST5 may include an HTL″, and the second common layer 223′″ of the fifth stack ST5 may include an ETL″. Depending on the case, the HTL, HTL′, HTL″, HTL″, and HTL′″ respectively included in the first common layers 221, 221′, 221″, 221″, and 221″ may include a same material or different materials from one another. In addition, the ETL, ETL′, ETL″, ETL″, and ETL″ respectively included in the second common layers 223, 223′, 223″, 223″, and 223″ may include a same material or different materials from one another.

In one or more embodiments, the characteristics of each layer of the organic light-emitting element 200″ shown in FIG. 4 may each independently and respectively be the same as those of FIG. 3 except that the organic light-emitting element 200″ includes a stack of five or more emitting units. Accordingly, hereinafter, because each of layers stacked on the first electrode 210 is described with reference to FIG. 3, and FIG. 4 is also the same, the description of FIG. 3 may be referred to for repeated contents.

The organic light-emitting element 200″ of FIG. 3 may include a first electrode 210, a second electrode 230, and an intermediate layer 220 arranged between the first electrode 210 and the second electrode 230. The intermediate layer 220 may include the first stack ST1, a charge generation layer 224 on the first stack ST1, and the second stack ST2 on the charge generation layer 224.

The first electrode 210 may be patterned for each organic light-emitting element 200″, and the second electrode 230 may be integrally provided over a plurality of organic light-emitting elements 200″.

Hereinafter, the layers stacked on the first electrode 210 are described in more detail.

The first stack ST1 may be arranged on the first electrode 210. The first stack ST1 may include the first common layer 221, the first emission layer 222a, and the second common layer 223.

As an example, although the hole transport region may have a single-layered structure including a single layer including a plurality of different materials, or a multi-layered structure including a hole injection layer/a hole transport layer, a hole injection layer/a hole transport layer/an emission auxiliary layer, a hole injection layer/an emission auxiliary layer, a hole transport layer/an emission auxiliary layer, or a hole injection layer/a hole transport layer/an electron blocking layer, each constituent layer sequentially stacked from the first electrode, the hole transport region is not limited thereto.

In one or more embodiments, it is shown in FIG. 3 that the organic light-emitting element 200″ includes an HIL and an HTL as a hole transport region. The HIL may be arranged to be adjacent to the first electrode 210, and the HTL may be arranged on the HIL.

The HIL may facilitate hole injection. Although, in one or more embodiments, the HIL may include at least one of HATCN, CuPc(cupper phthalocyanine), PEDOT(poly(3,4)-ethylenedioxythiophene), PANI(polyaniline), or NPD(N, N-dinaphthyl-N, N′-diphenylbenzidine), embodiments of the present disclosure are not limited thereto.

The HTL may include, as a host of the HTL, a triphenylamine derivative having high hole mobility and high stability such as TCTA, TPD(N, N′-diphenyl-N,N′-bis(3-methylphenyl)-1, 1′-bi-phenyl-4,4′-diamine), and/or NPB(N,N′-di(naphthalen-1-yl)-N,N′-diphenyl-benzidine). Although the HTL is shown as a single layer in FIG. 3, the HTL may have a multi-layered structure. The HTL may have a multi-layered structure of two or more layers including different materials selected from among the above materials. For example, in one or more embodiments, the HTL may include a double layer including NPB and TCTA.

The first emission layer 222a may be arranged on the first common layer 221. The first emission layer 222a may include an organic material emitting red, blue, or green light. For example, in embodiments in which the first emission layer 222a is to emit red light, the first emission layer 222a may be formed by using, for example, a red dopant (i.e., dopant that emits red light) as a preset host material. In one or more embodiments, in the case where the first emission layer 222a is to emit green light, the first emission layer 222a may be formed by using, for example, a green dopant (i.e., dopant that emits green light) as a preset host material. In one or more embodiments, in the case where the first emission layer 222a is to emit blue light, the first emission layer 222a may be formed by using, for example, a blue dopant (i.e., dopant that emits blue dopant) as a preset host material.

The second common layer 223 may be arranged on the first emission layer 222a. The second common layer 223 may serve as an electron transport region. The second common layer 223 may include at least one of a buffer layer, a hole blocking layer, an electron adjusting layer, or an electron transport layer (ETL). The thicknesses of the buffer layer, the hole blocking layer, the electron adjusting layer, and the ETL may be independently provided.

As an example, although the electron transport region may have a single-layered structure including a single layer including a plurality of different materials, or a structure including an electron transport layer, a hole blocking layer/an electron transport layer, an electron adjusting layer/an electron transport layer, or a buffer layer/an electron transport layer, each constituent layer sequentially stacked from the emission layer, the electron transport region is not limited thereto.

In one or more embodiments, it is shown in FIG. 3 that the organic light-emitting element 200″ includes an ETL as an electron transport region of the first stack ST1. The ETL may be arranged on the first emission layer 222a.

The ETL facilitates electron transport. Although, in one or more embodiments, the ETL may include at least one of Alq3(tris(8-hydroxyquinolinato) aluminum), PBD, TAZ, spiro-PBD, BAlq, Liq(lithium quinolinolate), BMB-3T, PF-6P, TPBI, COT, and SAlq, embodiments of the present disclosure are not limited thereto.

Although it is shown in FIG. 3 that the first stack ST1 of the organic light-emitting element 200″ includes all of the HIL, the HTL, and the ETL, embodiments of the disclosure are not necessarily limited thereto. In one or more embodiments, at least one of the HIL, the HTL, or the ETL may not be provided.

In one or more embodiments, remaining layers other than the first and second emission layers 222a and 222b, for example, the HIL, the HTL, and the ETL may be integrally provided over a plurality of organic light-emitting elements 200″.

The charge generation layer 224 may be arranged on the second common layer 223. The charge generation layer 224 may be arranged between the first stack ST1 and the second stack ST2. In FIG. 3, the charge generation layer 224 may be arranged between the ETL of the first stack ST1 and an HTL′ of the second stack ST2.

In one or more embodiments, the charge generation layer 224 may include an n-type (kind) charge (e.g., N-charge) generation layer n-CGL for supplying electrons to the first stack ST1, and a p-type (kind) charge (e.g., P-charge) generation layer p-CGL for supplying holes to the second stack ST2.

The n-type (kind) charge generation layer n-CGL may include an n-type (kind) dopant material and an n-type (kind) host material. In one or more embodiments, a volume ratio of the n-type (kind) host material to the n-type (kind) dopant material may be about 99:1 to about 90:10. The n-type (kind) dopant material may be a metal dopant, and the n-type (kind) host material may be an organic material, for example, an organic semiconductor material.

The n-type (kind) dopant material may be a metal of Group 1 and Group 2 of the periodic table, an organic material capable of injecting electrons, or a (e.g., any suitable) mixture thereof. For example, the n-type (kind) dopant material may be one or more selected from an alkali metal and an alkaline earth metal. For example, in one or more embodiments, the n-type (kind) charge generation layer n-CGL may include an organic layer doped with an alkali metal such as lithium (Li), sodium (Na), potassium (K), and/or cesium (Cs), an alkaline earth metal such as magnesium (Mg), strontium (Sr), and/or barium (Ba), radium (Ra), and/or ytterbium (Yb), but embodiments of the present disclosure are not limited thereto. In one or more embodiments, the n-type (kind) dopant material may include one or more rare earth elements of the lanthanide series. For example, in one or more embodiments, the n-type (kind) dopant material may be one selected from among dysprosium (Dy), europium (Eu), and samarium (Sm). For the n-type (kind) dopant material, a metal having a work function of less than about 3 eV may be used.

The n-type (kind) host material may include a material capable of transferring electrons, for example, at least one selected from among tris(8-hydroxyquinolinato)aluminum (Alq3), 8-hydroxyquinolinolato-lithium (Liq), 2-(biphenyl-4-yl)-5-(4-tert-butylphenyl)-1,3,4 oxadiazole (PBD), 3-(4-biphenyl) 4-phenyl-5-tert-butylphenyl-1,2,4-triazole (TAZ), spiro-PBD, and bis(2-methyl-8-quinolinolate)-4-(phenylphenolato)aluminum (BAlq), SAlq, 2,2′,2-(1,3,5-benzinetriyl)-tris(1-phenyl-1-H-benzimidazole)(TPBi), oxadiazole, triazole, phenanthroline, benzoxazole, and benzothiazoles, but embodiments of the present disclosure are not limited thereto.

The p-type (kind) charge generation layer p-CGL may include a p-type (kind) dopant material and a p-type (kind) host material. In one or more embodiments, a volume ratio of the p-type (kind) host material to the p-type (kind) dopant material may be about 99:1 to about 80:20. The p-type (kind) host material and the p-type (kind) dopant material may each be an organic material, and for example, the p-type (kind) host material may be a first organic semiconductor material, and the p-type (kind) dopant material may be a second organic semiconductor material or a metal material.

The p-type (kind) dopant material may include a metal oxide, an organic material such as tetrafluoro-tetracyanoquinodimethane (F4-TCNQ), HAT-CN (Hexaazatriphenylene-hexacarbonitrile), hexaazatriphenylene, and/or a metal oxide material such as V₂O₅, MoOₓ, WO₃, but embodiments of the present disclosure are not limited to. The p-type (kind) host material may include a material capable of transporting holes, for example, a material including at least one selected from among NPD (N,N-dinaphthyl-N,N′-diphenyl benzidine)(N,N′-bis(naphthalene-1-yl)-N,N′-bis(phenyl)-2,2′-dimethylbenzidine), TPD (N,N′-bis-(3-methylphenyl)-N, N′-bis-(phenyl)-benzidine), and MTDATA (4,4′,4-Tris(N-3-methylphenyl-N-phenyl-amino)-triphenylamine), but embodiments of the present disclosure are not limited thereto.

The n-type (kind) charge generation layer n-CGL and the p-type (kind) charge generation layer p-CGL may each be formed to have a thickness of about 1 Å to about 200 Å. In embodiments in which the thicknesses of the n-type (kind) charge generation layer n-CGL and the p-type (kind) charge generation layer p-CGL satisfy the above-described range, satisfactory charge transport characteristics may be obtained without a substantial increase in driving voltage.

The second stack ST2 may be arranged on the charge generation layer 224. The second stack ST2 may include a first common layer 221′, a second emission layer 222b, and a second common layer 223′.

The first common layer 221′ is a hole transport region and may include an HTL′. For example, the HTL′ may be arranged on the p-type (kind) charge generation layer p-CGL. In one or more embodiments, the HTL′ may include the same material as a material of the HTL included in the first stack ST1. In one or more embodiments, in the case where the second emission layer 222b emits light of a color different from a color of light emitted from the first emission layer 222a, the HTL′ included in the second stack ST2 may include a material different from a material of the HTL included in the first stack ST1.

The second emission layer 222b may be arranged on the HTL′. The second emission layer 222b may include an organic material emitting red, blue, or green light. For example, in one or more embodiments, in the case where the second emission layer 222b is to emit red light, the second emission layer 222b may be formed by using, for example, a red dopant (i.e., dopant that emits red light) as a preset host material. In one or more embodiments, in the case where the second emission layer 222b is to emit green light, the second emission layer 222b may be formed by using, for example, a green dopant (i.e., dopant that emits green light) as a preset host material. In one or more embodiments, in the case where the second emission layer 222b is to emit blue light, the second emission layer 222b may be formed by using, for example, a blue dopant (i.e., dopant that emits blue light) as a preset host material.

In one or more embodiments, the first emission layer 222a and the second emission layer 222b may be to emit light of the same wavelength or emit light of different wavelengths. For example, in one or more embodiments, both (e.g., simultaneously) the first emission layer 222a and the second emission layer 222b may be to emit blue light. In one or more embodiments, the first emission layer 222a may be to emit blue light, and the second emission layer 222b may be to emit green light. However, embodiments of the disclosure are not limited thereto.

The second common layer 223′ may be arranged on the second emission layer 222b. The second common layer 223′ may serve as an electron transport region. In one or more embodiments, the second common layer 223′ may include an ETL′.

In one or more embodiments, the ETL′ included in the second stack ST2 may include the same material as a material of the ETL included in the first stack ST1. In one or more embodiments, in the case where the second emission layer 222b emits light of a color different from a color of light emitted from the first emission layer 222a, the ETL′ included in the second stack ST2 may include a material different from a material of the ETL included in the first stack ST1.

An EIL may be excluded from the second common layer 223′. As described below, it may be understood that, because the second electrode 230 serves as an EIL concurrently (e.g., simultaneously), an EIL is not separately and individually provided to the second common layer 223′.

The organic light-emitting element 200″ described with reference to FIG. 3 may include the second electrode 230 on the second common layer 223′ of the second stack ST2. Like the common layers 221, 223, 221′, and 223′ described above, the second electrode 230 may be integrally provided over a plurality of organic light-emitting elements 200″.

The second electrode 230 requires a low surface resistance to increase a power efficiency and improve a voltage drop (IR drop) phenomenon. In this regard, a trade-off relationship is established in which a light absorption rate of the second electrode 230 increases and the light efficiency of the organic light-emitting element 200″ decreases. Accordingly, it is desired or required to implement the second electrode 230 having a low surface resistance and having a low light absorption rate, concurrently (e.g., simultaneously).

In one or more embodiments, the second electrode 230 included in the organic light-emitting element 200″ according to one or more embodiments may have the same structure as a structure of the second electrode 230 described with reference to FIG. 1. For example, the second electrode 230 may include about 3 vol % to about 30 vol % of an alkali metal in a conductive material and may include, for example, Li or Na as the alkali metal.

In one or more embodiments, the second electrode 230 included in the organic light-emitting element 200″ according to one or more embodiments may have the same structure as a structure of the second electrode 230 described with reference to FIG. 2. For example, the second electrode 230 may further include an alkali metal in a conductive material and may have a concentration gradient of alkali metal in a cross-section within the second electrode 230.

In one or more embodiments, the second electrode 230 of FIG. 1 or FIG. 2 may be utilized as a resonant electrode of other photoelectric elements in addition to the electrodes for the organic light-emitting elements 200, 200′, 200″, and 200′″ described in FIGS. 1 to 4. For example, the second electrode 230 may be utilized as an electrode of an organic light-emitting diode (OLED), a light-emitting diode (LED), a quantum dot light-emitting diode (QLED), a perovskite-LED, a solar cell, a secondary battery, a nuclear battery, and/or the like.

FIG. 5A and FIG. 5B are each a schematic plan view showing a display apparatus according to one or more embodiments of the present disclosure.

At least one selected from among the organic light-emitting elements 200, 200′, 200″, and 200′″ of FIGS. 1 to 4 may be applicable to the display apparatus described with reference to FIG. 5A and FIG. 5B.

The display apparatus may be used as a display screen of one or more

suitable products including televisions, notebook computers, monitors, advertisement boards, Internet of things (loTs) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus according to one or more embodiments may be used in wearable devices including smartwatches, watchphones, glasses-type (kind) displays, and head-mounted displays (HMDs). In addition, in one or more embodiments, the display apparatus 1 may be applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

Referring to FIG. 5A and FIG. 5B, display apparatuses 1 and 1′ each having a display area DA of an approximately rectangular shape are shown. Referring to FIG. 5A and FIG. 5B, one or more suitable kinds of elements may be arranged on a substrate 100 that has a long axis and a short axis. In a user's viewpoint, FIG. 5A shows the display apparatus 1 having a short axis in a horizontal direction (e.g., an x direction) and a long axis in a vertical direction (e.g., a y direction), and FIG. 5B shows the display apparatus 1′ having a long axis in a horizontal direction (e.g., an x direction) and a short axis in a vertical direction (e.g., a y direction). In the display apparatuses 1 and 1′ according to one or more embodiments, a printed circuit board PCB may be arranged in the short axis direction of the display apparatus 1 as in FIG. 5A, and a printed circuit board PCB may be arranged in both the short and long axes directions of the display apparatus 1′ as in FIG. 5B. In one or more embodiments, the display apparatus 1 shown in FIG. 5A may be used in small and medium-sized electronic apparatuses such as mobile phones, smartphones, tablet personal computers (PCs), mobile communication terminals, electronic organizers, electronic books, and portable multimedia players (PMPs), and the display apparatus 1′ shown in FIG. 5B may be used in large-sized electronic apparatuses such as televisions, notebook computers, monitors, and advertisement boards.

First, referring to FIG. 5A, the display apparatus 1 may be formed by attaching the substrate 100 to an upper substrate 700 through a sealing member 600. For example, the upper substrate 700 may be provided in a smaller size than the substrate 100 to expose a pad part 30. The sealing member 600 may be formed along outer surfaces of the substrate 100 and the upper substrate 700 to be around (e.g., surround) them to attach the substrate 100 to the upper substrate 700. In one or more embodiments, the sealing member 600 may not be provided.

The display apparatus 1 may include a display area DA and a peripheral area PA outside the display area DA. The display apparatus 1 may be configured to display images by using light emitted from a plurality of pixels P arranged in the display area DA. Hereinafter, in the present disclosure, a pixel P may denote a sub-pixel substantially including one organic light-emitting element.

The display area DA may include the pixels P, wherein the pixels P are connected to data lines DL extending in the y direction, and scan lines SL extending in the x direction crossing the y direction. Each pixel P is connected to a driving voltage line PL extending in the y direction.

The pixels P may respectively include display elements such as the organic light-emitting elements 200, 200′, 200″, and/or 200′″ described with reference to FIGS. 1 to 4. Each pixel P may be configured to emit, for example, red, green, blue, or white light from the organic light-emitting diode. In one or more embodiments, a color of each pixel P may be implemented by a color filter and/or the like arranged on the organic light-emitting element, separately from a color of light emitted from the organic light-emitting elements included in the pixels P.

Each pixel P may be electrically connected to built-in circuits arranged in the peripheral area PA. A first power supply line 10, a second power supply line 20, and the pad part 30 may be arranged in the peripheral area PA.

The first power supply line 10 may be arranged to correspond to one side of the display area DA. The first power supply line 10 may be connected to a plurality of driving voltage lines PL transferring a driving voltage ELVDD (see FIG. 6A or FIG. 6B) to a pixel P.

The second power supply line 20 may have a loop shape having one open side to partially be around (e.g., surround) the display area DA. The second power supply line 20 may provide a common voltage ELVSS (see FIG. 6A or FIG. 6B) to a second electrode of the pixel P. The second power supply line 20 may be call a common voltage supply line.

The pad part 30 may include a plurality of pads 31 and be arranged on one side of the substrate 100. Each of the pads 31 may be connected to a first connection line 41 connected to the first power supply line 10, or connection lines 51 extending to the display area DA. The pads 31 of the pad part 30 may be exposed by not being covered by an insulating layer, and electrically connected to a printed circuit board PCB. A terminal part PCB-P of the printed circuit board PCB may be electrically connected to the pad part 30.

The printed circuit board PCB is configured to transfer signals or power of a controller to the pad part 30. The controller may respectively provide the driving voltage ELVDD and the common voltage ELVSS (see FIG. 6A or FIG. 6B) to the first and second power supply lines 10 and 20 through first and second connection lines 41 and 42.

A data driving circuit 60 is electrically connected to the data line DL. A data signal of the data driving circuit 60 may be provided to each pixel P through the connection line 51 and the data line DL, wherein the connection line 51 is connected to the pad part 30, and the data line DL is connected to the connection line 51. Although it is shown in FIG. 5B that the data driving circuit 60 is arranged on the printed circuit board PCB, the data driving circuit 60 may be arranged on the substrate 100 in one or more embodiments. For example, in one or more embodiments, the data driving circuit 60 may be arranged between the pad part 30 and the first power supply line 10.

The display apparatus 1′ of FIG. 5B is similar to the display apparatus 1 of FIG. 5A. However, it is shown in FIG. 5A that one printed circuit board PCB is attached to the pad part 30, and it is shown in FIG. 5B that a plurality of printed circuit boards PCB may be attached to the pad part 30. In FIG. 5B, the pad parts 30 may be arranged along two sides of the substrate 100. The pad part 30 may include a plurality of sub-pad parts 30S, and one printed circuit board PCB may be attached to each sub-pad part 30S.

In one or more embodiments, the organic light-emitting element 200 of FIG. 1 and the organic light-emitting element 200′ of FIG. 2 may be employed together within one display apparatus. For example, in the display apparatuses 1 and 1′, a first pixel P1 arranged at (e.g., in or in proximity to) an edge of the display area DA may include a first organic light-emitting element 200-1 like the organic light-emitting element 200 of FIG. 1, and a second pixel P2 arranged in the central portion of the display area DA may include a second organic light-emitting element 200-2 like the organic light-emitting element 200′ of FIG. 2.

For example, referring to FIG. 5A, in one display apparatus 1, the first pixel P1 arranged at (e.g., in or in proximity to) an edge of the display area DA may have a structure of the second electrode 230 in which the conductive material and the alkali metal are mixed without a concentration gradient as described with reference to FIG. 1, and the second pixel P2 arranged in the central portion of the display area DA may have a structure of the second electrode 230 in which the alkali metal has a concentration gradient within the second electrode 230 as described with reference to FIG. 2. For example, in one or more embodiments, in the second electrode 230 integrally provided in the display area DA, a portion of the second electrode 230 included in the first organic light-emitting element 200-1 is designated as a first portion, and a portion of the second electrode 230 included in the second organic light-emitting element 200-2 is designated as a second portion, proportions of the alkali metal within the second electrode 230 in the first portion and the second portion may be different from each other.

Because the second electrode 230 described with reference to FIGS. 1 to 4 is supplied with power through the second power supply line 20 arranged outside the display area DA as shown in FIG. 5A, the second electrode 230 shows a tendency for electrical characteristics, such as a voltage drop, to deteriorate toward the central portion of the display area DA. Accordingly, in the case of the second pixel P2 arranged in the central portion of the display area DA, a region in which the proportion of the conductive material (e.g., Ag) having a low work function is relatively high is formed by allowing the alkali metal to have a concentration gradient within the second electrode 230 (that is, the second portion of the second electrode 230). Therefore, electrical characteristics of the second electrode 230 of the second pixel P2 may be improved compared to the second electrode 230 (that is, the first portion of the second electrode 230) of the first pixel P1. For example, the first pixel P1 near the edge of the display area has a second electrode where the conductive material and alkali metal are mixed without a concentration gradient. In contrast, the second pixel P2 at (e.g., in) the central portion has a second electrode with an alkali metal concentration gradient. The second electrode is powered through a supply line outside the display area, leading to electrical characteristics like voltage drop deteriorating toward the center. By forming a region with a higher proportion of conductive material (e.g., Ag) in the central portion of the second electrode, the electrical characteristics of the second pixel P2 are improved compared to the first pixel P1.

Although the display apparatus 1 of FIG. 5A is described as an example of the above-described structure, the first pixel P1 and the second pixel P2 of the display apparatus 1′ of FIG. 5B may also have the same structure as that described above.

FIG. 6A and FIG. 6B are each an equivalent circuit diagram of a pixel of a display apparatus according to one or more embodiments of the present disclosure.

Referring to FIG. 6A, each pixel P may be implemented by the pixel circuit PC and the organic light-emitting element (hereinafter, referred to as the organic light-emitting diode OLED) connected to the pixel circuit PC, wherein the pixel circuit PC is connected to the scan line SL and the data line DL. In one or more embodiments, the pixel circuit PC may include a driving thin-film transistor T1, a switching thin-film transistor T2, and a storage capacitor Cst. The switching thin-film transistor T2 may be connected to the scan line SL and the data line DL, and configured to transfer a data signal Dm to the driving thin-film transistor T1 according to a scan signal Sn, wherein the data signal Dm is input through the data line DL, and the scan signal Sn is input through the scan line SL.

The storage capacitor Cst may be connected to the switching thin-film transistor T2 and the driving voltage line PL and configured to store a voltage corresponding to a difference between a voltage transferred from the switching thin-film transistor T2 and the driving voltage ELVDD supplied to the driving voltage line PL.

The driving thin-film transistor T1 may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current.

Although it is described with reference to FIG. 6A that the pixel circuit PC includes two thin-film transistors and one storage capacitor, embodiments of the present disclosure are not limited thereto.

Referring to FIG. 6B, in one or more embodiments, the pixel circuit PC may include the driving thin-film transistor T1, the switching thin-film transistor T2, a sensing thin-film transistor T3, and the storage capacitor Cst.

The scan line SL may be connected to a gate electrode G2 of the switching thin-film transistor T2, the data line DL may be connected to a source electrode S2 of the switching thin-film transistor T2, and a first electrode CE1 of the storage capacitor Cst may be connected to a drain electrode D2 of the switching thin-film transistor T2.

Accordingly, the switching thin-film transistor T2 may be configured to supply a data voltage of the data line DL to a first node N in response to a scan signal Sn from the scan line SL of each pixel P.

A gate electrode G1 of the driving thin-film transistor T1 may be connected to the first node N, a source electrode S1 of the driving thin-film transistor T1 may be connected to the driving voltage line PL configured to transfer a driving voltage ELVDD, and a drain electrode D1 of the driving thin-film transistor T1 may be connected to an anode electrode of the organic light-emitting diode OLED.

Accordingly, the driving thin-film transistor T1 may be configured to adjust the amount of a current flowing through the organic light-emitting diode OLED according to a source-gate voltage (Vgs) of itself, that is, a voltage applied between the driving voltage ELVDD and the first node N.

A sensing control line SSL may be connected to a gate electrode G3 of the sensing thin-film transistor T3, a source electrode S3 of the sensing thin-film transistor T3 may be connected to a second node S, and a drain electrode D3 of the sensing thin-film transistor T3 may be connected to a reference voltage line RL. In one or more embodiments, the sensing thin-film transistor T3 may be controlled or selected by the scan line SL instead of the sensing control line SSL.

The sensing thin-film transistor T3 may sense an electric potential of a first electrode (e.g., an anode) of the organic light-emitting diode OLED. The sensing thin-film transistor T3 may be configured to supply a pre-charging voltage from the reference voltage line RL to the second node S in response to a sensing signal SSn from the sensing control line SSL, or supply a voltage of the first electrode (e.g., the anode) of the organic light-emitting diode OLED to the reference voltage line RL during a sensing period.

The first electrode CE1 of the storage capacitor Cst may be connected to the first node N, and a second electrode CE2 of the storage capacitor Cst may be connected to the second node S. The storage capacitor Cst may be charged with a difference voltage between voltages respectively supplied to the first and second nodes N and S, and may be configured to supply the difference voltage as a driving voltage of the driving thin-film transistor T1. For example, the storage capacitor Cst may be charged with a difference voltage between a data voltage Dm and a pre-charging voltage (Vpre) respectively supplied to the first and second nodes N and S.

A bias electrode BSM may be formed to correspond to the driving thin-film transistor T1 and connected to the source electrode S3 of the sensing thin-film transistor T3. Because the bias electrode BSM receives a voltage in cooperation with the potential of the source electrode S3 of the sensing thin-film transistor T3, the driving thin-film transistor T1 may be stabilized. In one or more embodiments, the bias electrode BSM may not be connected to the source electrode S3 of the sensing thin-film transistor T3 but may be connected to a separate bias line.

A second electrode (e.g., a cathode) of the organic light-emitting diode OLED may receive a common voltage ELVSS. The organic light-emitting diode OLED may be to emit light by receiving a driving current from the driving thin-film transistor T1.

Although it is shown in FIG. 6B that the signal lines, that is, the scan line SL, the sensing control line SSL, and the data line DL, the reference voltage line RL, and the driving voltage line PL are provided for each pixel P, embodiments of the disclosure are not limited thereto. For example, in one or more embodiments, at least one selected from the signal lines, that is, the scan line SL, the sensing control line SSL, and the data line DL, and/or the reference voltage line RL, and the driving voltage line PL may be shared by adjacent pixels.

The pixel circuit PC is not limited to the number of thin-film transistors, the number of storage capacitors, and the circuit design described with reference to FIG. 6A and FIG. 6B, and the number of thin-film transistors, the number of storage capacitors, and the circuit design may be variously changed.

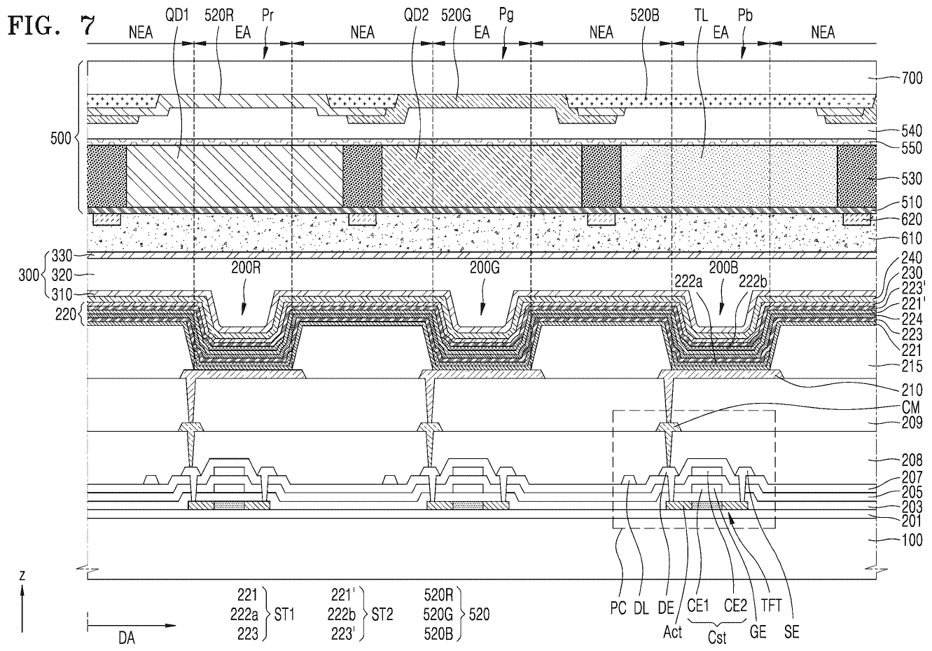

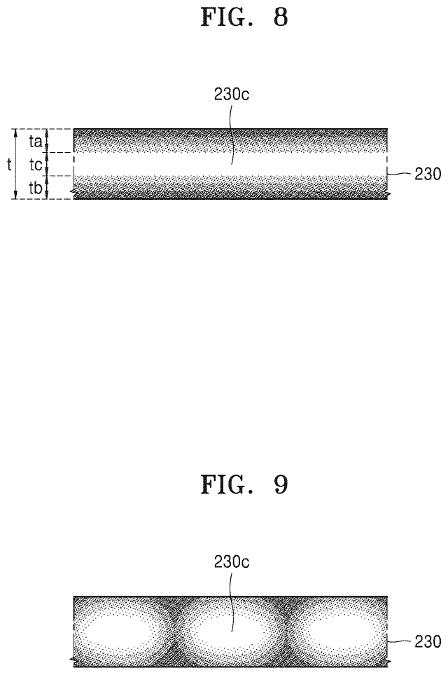

FIG. 7 is a schematic cross-sectional view of a portion of a display apparatus according to one or more embodiments of the present disclosure, and FIG. 8 and FIG. 9 are each a schematic cross-sectional view of the second electrode according to one or more embodiments of the present disclosure.

The display apparatus according to one or more embodiments may include at least one selected from among the organic light-emitting elements 200, 200′, 200″, and 200′″ described with reference to FIGS. 1 to 4. It is shown in FIG. 7 that the display apparatus has a tandem structure of FIG. 3 in which two emission layers are vertically stacked among the organic light-emitting elements 200, 200′, 200″, and 200′″ described with reference to FIGS. 1 to 4. In one or more embodiments, an organic light-emitting element including one emission layer is applicable to the display apparatus of FIG. 7, or an organic light-emitting element in which three or more emission layers are stacked is applicable to the display apparatus of FIG. 7.

Referring to FIG. 7, first to third pixels Pr, Pg, and Pb are arranged on a substrate 100. The first to third pixels Pr, Pg, and Pb may include first to third organic light-emitting elements 200R, 200G, and 200B, respectively, and respective pixel circuits PC, and each of the first to third organic light-emitting elements 200R, 200G, and 200B may be electrically connected to its respective pixel circuit PC, and thus, light emission thereof may be controlled or selected. In the description, because the pixel circuits PC included in the first to third pixels Pr, Pg, and Pb have a same structure, a stack structure of one pixel is mainly described in more detail.

First, the substrate 100 may include glass or a polymer resin. In one or more embodiments, the substrate 100 may include a plurality of sub-layers. The plurality of sub-layers may have a structure in which an organic layer and an inorganic layer are alternately stacked. In embodiments in which the substrate 100 includes a polymer resin, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

A buffer layer 201 may be formed on the substrate 100, wherein the buffer layer 201 is formed to prevent or reduce impurities from penetrating to a semiconductor layer Act of a thin-film transistor TFT. The buffer layer 201 may include an inorganic insulating material such as silicon nitride, silicon oxynitride, and/or silicon oxide, and include a single layer or a multi-layer including one or more of the above inorganic insulating materials.

The pixel circuit PC may be arranged on the buffer layer 201. The pixel circuit PC may be arranged to correspond to each pixel P.

The pixel circuit PC includes the thin-film transistor TFT and a storage capacitor Cst. The thin-film transistor TFT may include the semiconductor layer Act, a gate electrode GE, a source electrode SE, and a drain electrode DE.

In one or more embodiments, the data line DL of the pixel circuit PC is electrically connected to a switching thin-film transistor included in the pixel circuit PC. In the present embodiment, although a top-gate type (kind) thin-film transistor in which the gate electrode GE is arranged over the semiconductor layer Act with a gate insulating layer 203 therebetween is shown, the thin-film transistor TFT may be a bottom-gate type (kind) thin-film transistor in one or more embodiments.

In one or more embodiments, the semiconductor layer Act may include an oxide semiconductor. In one or more embodiments, the semiconductor layer Act may include amorphous silicon, polycrystalline silicon, or an organic semiconductor.

The gate electrode GE may include a low-resistance metal material. The gate electrode GE may include a conductive material including molybdenum (Mo), aluminum (Al), copper (Cu), and/or titanium (Ti) and have a single-layered structure or a multi-layered structure including one or more of the above materials.

The gate insulating layer 203 between the semiconductor layer Act and the gate electrode GE may include an inorganic insulating material including silicon oxide, silicon nitride, silicon oxynitride, aluminum oxide, titanium oxide, tantalum oxide, hafnium oxide and/or the like. The gate insulating layer 203 may include a single layer or a multi-layer including one or more of the above materials.

The source electrode SE and the drain electrode DE may be arranged on a same layer as a layer on which the data line DL is arranged and may include the same material as a material of the data line DL. The source electrode SE, the drain electrode DE, and the data line DL may each include a material having high conductivity. The source electrode SE and the drain electrode DE may each include a conductive material including molybdenum (Mo), aluminum (Al), copper (Cu), and/or titanium (Ti) and include a single layer or a multi-layer including one or more of the above materials. For example, in one or more embodiments, the source electrode SE, the drain electrode DE, and the data line DL may each include a multi-layered structure of Ti/Al/Ti.

The storage capacitor Cst may include a first electrode CE1 and a second electrode CE2 overlapping each other with a first interlayer insulating layer 205 therebetween. The storage capacitor Cst may overlap the thin-film transistor TFT. With regard to this, it is shown in FIG. 7 that the gate electrode GE of the thin-film transistor TFT serves as the first electrode CE1 of the storage capacitor Cst. In one or more embodiments, the storage capacitor Cst may not overlap the thin-film transistor TFT. The storage capacitor Cst may be covered by a second interlayer insulating layer 207. The second electrode CE2 of the storage capacitor Cst may include a conductive material including molybdenum (Mo), aluminum (Al), copper (Cu), and/or titanium (Ti) and have a single-layered structure or a multi-layered structure including one or more of the above materials.

The first interlayer insulating layer 205 and the second interlayer insulating layer 207 may each include an inorganic insulating material including silicon oxide, silicon nitride, silicon oxynitride, aluminum oxide, titanium oxide, tantalum oxide, hafnium oxide, and/or the like. The first interlayer insulating layer 205 and the second interlayer insulating layer 207 may each include a single layer or a multi-layer including one or more of the above materials.

The pixel circuit PC including the thin-film transistor TFT and the storage capacitor Cst may be covered by a first planarization insulating layer 208. The first planarization insulating layer 208 may include an approximately or substantially flat upper surface.

In one or more embodiments, a third interlayer insulating layer may be further arranged under the first planarization insulating layer 208 to cover the source electrode SE, the drain electrode DE, and the data line DL. The third interlayer insulating layer may include an inorganic insulating material such as silicon oxide, silicon nitride, and/or silicon oxynitride.

The pixel circuit PC may be electrically connected to a first electrode 210. For example, as shown in FIG. 7, in one or more embodiments, a contact metal layer CM may be arranged between the thin-film transistor TFT and the first electrode 210. The contact metal layer CM may be connected to the thin-film transistor TFT through a contact hole formed in the first organic planarization layer 208, and the first electrode 210 may be connected to the contact metal layer CM through a contact hole formed in a second planarization insulating layer 209 on the contact metal layer CM. The contact metal layer CM may include a conductive material including molybdenum (Mo), aluminum (Al), copper (Cu), and/or titanium (Ti) and have a single-layered structure or a multi-layered structure including one or more of the above materials. In one or more embodiments, the contact metal layer CM may include a multi-layer of Ti/Al/Ti.

The first planarization insulating layer 208 and the second planarization insulating layer 209 may each include an organic insulating material including a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. In one or more embodiments, the first planarization insulating layer 208 and the second planarization insulating layer 209 may each include polyimide.

The first to third organic light-emitting elements 200R, 200G, and 200B may be each arranged on the second planarization insulating layer 209. For example, each of the first to third organic light-emitting elements 200R, 200G, and 200B may have a tandem structure described with reference to FIG. 3.

Each of the first to third organic light-emitting elements 200R, 200G, and 200B may include the first electrode 210, a first stack ST1, a charge generation layer 224, a second stack ST2, and a second electrode 230. As described above with reference to FIG. 3, the first stack ST1 may include a first common layer 221, a first emission layer 222a, and a second common layer 223, and the second stack ST2 may include a first common layer 221′, a second emission layer 222b, and a second common layer 223′. In the first to third organic light-emitting elements 200R, 200G, and 200B, the first electrode 210, the first emission layer 222a, and the second emission layer 222b may be patterned for each pixel, and the first common layer 221, the second common layer 223, the charge generation layer 224, and the second electrode 230 are integrally provided in the display area DA.

It is shown in FIG. 7 that the first to third organic light-emitting elements 200R, 200G, and 200B have the stack structure of FIG. 3 as an example. In one or more embodiments, the first to third organic light-emitting elements 200R, 200G, and 200B may employ at least one selected from among the stack structures of FIGS. 1 to 4.

In one or more embodiments, the first electrode 210 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In one or more embodiments, the first electrode 210 may further include a layer on and/or under the reflective layer, the layer including ITO, IZO, ZnO, and/or In₂O₃. In one or more embodiments, the first electrode 210 may include a single-layered structure including (e.g., consisting of) a single layer, or a multi-layered structure including a plurality of layers. For example, in one or more embodiments, the first electrode 210 may have a three-layered structure of ITO/Ag/ITO.

A pixel-defining layer 215 may be formed on the first electrode 210. The pixel-defining layer 215 may include an opening that exposes an upper surface of the first electrode 210, and cover edges of the first electrode 210. In one or more embodiments, the pixel-defining layer 215 may include an organic insulating material. In one or more embodiments, the pixel-defining layer 215 may include an inorganic insulating material such as silicon nitride, silicon oxynitride, and/or silicon oxide. In one or more embodiments, the pixel-defining layer 215 may include an organic insulating material and an inorganic insulating material.

An intermediate layer 220 may include two or more emission layers (e.g., the first emission layer 222a and the second emission layer 222b). Each of the first emission layer 222a and the second emission layer 222b may independently include a polymer material or a low molecular weight organic material capable of emitting light of a preset color. For example, both (e.g., simultaneously) the first emission layer 222a and the second emission layer 222b according to one or more embodiments may be to emit blue light.

In addition, the intermediate layer 220 may include the first common layer 221, the first emission layer 222a, the second common layer 223 of the first stack ST1, and the first common layer 221′, the second emission layer 222b, the second common layer 223′ of the second stack ST2, sequentially arranged on the first electrode 210, and the charge generation layer 224 between the first stack ST1 and the second stack ST2. Because description of the intermediate layer 220 is the same as that described with reference to FIG. 3, the description of FIG. 3 may be referred to for repeated contents.

The first common layer 221 of the first stack ST1 may be a single layer or a multi-layer. For example, in embodiments in which the first common layer 221 includes a polymer material, the first common layer 221 may include a hole transport layer (HTL), which has a single-layered structure, and may include polyethylene dihydroxythiophene (PEDOT: poly-(3,4)-ethylene-dihydroxy thiophene) or polyaniline (PANI: polyaniline). In embodiments in which the first common layer 221 includes a low molecular weight material, the first common layer 221 may include an HIL and an HTL.

The second common layer 223 of the first stack ST1 may be a single layer or a multi-layer. In one or more embodiments, the second common layer 223 of the first stack ST1 may not be provided depending on the case. In embodiments in which the first common layer 221, the first emission layer 222a, and the second emission layer 222b each include a polymer material, the second common layer 223 is formed. For example, the second common layer 223 may include an ETL.

The charge generation layer 224 may be arranged between the first stack ST1 and the second stack ST2. The charge generation layer 224 may include an n-type (kind) charge (e.g., N-charge) generation layer n-CGL and a p-type (kind) charge (e.g., P-charge) generation layer p-CGL. The charge generation layer 224 is the same as that described with reference to FIG. 3.

The first common layer 221′ of the second stack ST2 may be a single layer or a multi-layer. The first common layer 221′ may include a material same as or different from that of the first common layer 221.

The second common layer 223′ of the second stack ST2 may be a single layer or a multi-layer. The second common layer 223′ of the second stack ST2 may include a material same as or different from that of the second common layer 223. For example, in one or more embodiments, the second common layer 223′ may include an ETL.

The second electrode 230 may include a conductive material having a low

work function. For example, in one or more embodiments, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In one or more embodiments, the second electrode 230 may further include a layer on the (semi) transparent layer, the layer including ITO, IZO, ZnO, and/or In₂O₃.

In one or more embodiments, the second electrode 230 may further include an alkali metal in addition to the conductive material. The alkali metal refers to a metal in Group 1 of the periodic table, and may include, for example, lithium (Li) or sodium (Na). As such, because the second electrode 230 is formed to include the alkali metal, the second electrode 230 may serve as an electron injection layer, concurrently (e.g., simultaneously). As a result, an electron injection layer does not need to be substantially formed within the first to third organic light-emitting elements 200R, 200G, and 200B, and thus the structure of the element may be simplified. In addition, because the alkali metal has a low light absorption rate compared to other metal material, particularly, a reflective metal (e.g., Mg and/or the like), a light absorption rate of the entire second electrode 230 may be reduced through this, and thus, the element efficiency may be improved.

In one or more embodiments, the second electrode 230 may further include an alkali metal in addition to the conductive material, and as described with reference to FIG. 2, the second electrode 230 may have a concentration gradient of alkali metal in the cross-section of the second electrode 230. The proportion of alkali metal within the second electrode 230 may gradually increase from the central portion of the cross-section of the second electrode 230 to the surface layer of the second electrode 230.

The proportion of alkali metal within the second electrode 230 may be lowest in the central portion of the cross-section of the second electrode 230 and may gradually increase in a direction away from the central portion of the cross-section of the second electrode 230. For example, the proportion of alkali metal within the second electrode 230 may gradually increase from the central portion of the cross-section of the second electrode 230 toward the second common layer 223 and a capping layer 240.

For example, referring to FIG. 8, in one or more embodiments, there may be a region 230c in the central portion of the cross-section of the second electrode 230 that does not include alkali metal. In these embodiments, the region 230c may include only the conductive metal material (i.e., the conductive material). For example, in one or more embodiments, the region 230c may include pure Ag.

In one or more embodiments, a thickness tc of the region 230c may be about 30% to about 50% of an entire thickness t of the second electrode 230. An electrical resistance of the second electrode 230 may be effectively reduced by providing the thickness tc of the region 230c in about 30% to about 50% of the entire thickness t of the second electrode 230, and thus, sufficiently securing a region within the second electrode 230 in which the conductive metal having a low work function is concentrated.

Regions including the alkali metal may be respectively arranged on and under the region 230c. an upper region including the alkali metal may denote a region close to a capping layer 240 (see FIG. 7), and the lower region including the alkali metal may denote a region close to the second common layer 223′ (see FIG. 7). A thickness ta of the upper region including the alkali metal and a thickness tb of the lower region including the alkali metal may have a same ratio as the thickness tc of the region 230c with respect to the entire thickness t of the second electrode 230. For example, in one or more embodiments, a ratio of ta:tb:tc may be about 1:1:1. In one or more embodiments, the thickness ta of the upper region and the thickness tb of the lower region each including the alkali metal may have a different ratio from the thickness tc of the region 230c with respect to the entire thickness t of the second electrode 230. For example, in one or more embodiments, a ratio of ta:tb:tc may be about 1:2:3. For example, regions containing alkali metal are arranged above and below region 230c. The upper region is near the capping layer, and the lower region is near the second common layer. The thicknesses of these regions (ta and tb) and the central region (tc) can have the same ratio (e.g., 1:1:1) or different ratios (e.g., 1:2:3) with respect to the total thickness of the second electrode.

In one or more embodiments, the region 230c may be continuously formed as shown in FIG. 8, or may be discontinuously formed as shown in FIG. 9.

The capping layer 240 may be arranged on the second electrode 230. For example, the capping layer 240 may include a single layer or a multi-layer including an organic material, an inorganic material, and/or a (e.g., any suitable) mixture thereof. In one or more embodiments, a LiF layer may be arranged on the capping layer 240. In one or more embodiments, the capping layer 240 may not be provided.

Because the first to third organic light-emitting elements 200R, 200G, and 200B may be easily damaged by external moisture, oxygen, and/or the like, a thin-film encapsulation layer 300 may cover and protect the first to third organic light-emitting elements 200R, 200G, and 200B. The thin-film encapsulation layer 300 may cover the display area DA and extend to a non-display area outside the display area DA. The thin-film encapsulation layer 300 includes at least one organic encapsulation layer and at least one inorganic encapsulation layer. In one or more embodiments, the thin-film encapsulation layer 300 includes a first inorganic encapsulation layer 310, an organic encapsulation layer 320, and a second inorganic encapsulation layer 330.

The first inorganic encapsulation layer 310 may cover the second electrode 230 and may include silicon nitride, silicon oxynitride, and/or silicon oxide. Because the first inorganic encapsulation layer 310 is formed along a structure thereunder, an upper surface thereof is not flat. The organic encapsulation layer 320 may cover the first inorganic encapsulation layer 310 and, unlike the first inorganic encapsulation layer 310, an upper surface of the organic encapsulation layer 320 may be approximately flat. For example, the upper surface of a portion of the organic encapsulation layer 320 that corresponds to the display area DA may be approximately flat. The organic encapsulation layer 320 may include, for example, at least one of polyethylene terephthalate, polyethylene naphthalate, polycarbonate, polyimide, polyethylene sulfonate, polyoxymethylene, polyarylate, hexamethyldisiloxane, or an acryl-based resin (e.g., polymethylmethacrylate, poly acrylic acid, and/or the like). The second inorganic encapsulation layer 330 may cover the organic encapsulation layer 320 and may include silicon nitride, silicon oxynitride, and/or silicon oxide.

Even if (e.g., when) cracks occur inside the thin-film encapsulation layer 300, the thin-film encapsulation layer 300 may prevent or reduce the cracks from being connected between the first inorganic encapsulation layer 310 and the organic encapsulation layer 320 or between the organic encapsulation layer 320 and the second inorganic encapsulation layer 330 through the above multi-layered structure. With this configuration, forming of a path through which external moisture and/or oxygen penetrates the display area DA may be prevented or reduced.

A filler 610 may be arranged on the thin-film encapsulation layer 300. The filler 610 may perform a buffering function against external pressure and/or the like. The filler 610 may include an organic material such as a methyl silicone, a phenyl silicone, polyimide, and/or the like. However, the filler 610 is not limited thereto and may include an organic sealant such as a urethane-based resin, an epoxy-based resin, and/or an acryl-based resin, or an inorganic sealant such as silicone. For example, a refractive index of the filler 610 may be about 1.5 to about 1.7.

A color-converting panel 500 may be arranged in an upper portion opposite to (e.g., facing) the substrate 100 with the filler 610 therebetween. The color-converting panel 500 may include an upper substrate 700 and a color filter 520, first and second color-converting layers QD1 and QD2, a transmissive layer TL, a partition wall 530, a low refractive layer 540, a first barrier layer 510, and a second barrier layer 550 arranged on the upper substrate 700.

In one or more embodiments, a spacer 620 may be arranged between the color-converting panel 500 and the filler 610. The spacer 620 may be arranged to correspond to a non-emission area NEA.

Referring to FIG. 7, the first barrier layer 510 may be arranged on the spacer 620 and arranged to cap the first and second color-converting layers QD1 and QD2 and the transmissive layer TL. The first barrier layer 510 may include an inorganic material, and include, for example, silicon nitride, silicon oxynitride, and/or silicon oxide. The first barrier layer 510 may have a refractive index of about 1.4 to about 1.6.

Each of the first and second color-converting layers QD1 and QD2 may include quantum dots. Quantum dots represent unique excitation and emission characteristics depending on material and size thereof, and accordingly, convert incident light into light of a preset color. Various materials may be used for quantum dots.

In the present disclosure, quantum dots denote crystals of a semiconductor compound. Quantum dots may be to emit light of one or more suitable emission wavelengths according to a crystal size. Quantum dots may be to emit light of one or more suitable emission wavelengths by adjusting an element ratio within the quantum dot compound.

A diameter of the quantum dots may be, for example, about 1 nm to about 10 nm. In the present disclosure, when dot, dots, or dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dots may be synthesized by a wet chemical process, a metal organic chemical vapor deposition process, a molecular beam epitaxy process, or a similar process.

The wet chemical process is a method of mixing an organic solvent with a precursor material of a quantum dot and then growing quantum dot crystals. When the above crystals grow, the organic solvent naturally acts as a dispersant coordinated to the quantum dot crystal surface and may control the growth of the crystals. Accordingly, the wet chemical process is easier than vapor deposition method such as metal organic chemical vapor deposition (MOCVD) or molecular beam epitaxy (MBE), and may control the growth of the quantum dot particles through a process of low costs.

In one or more embodiments, a quantum dot may have a core-shell structure including a core and a shell, the core including a nano crystal, and the shell around (e.g., surrounding) the core.

The quantum dot may include a Group III-V semiconductor compound, a Group II-VI semiconductor compound, a Group III-V semiconductor compound, a Group I-III-VI semiconductor compound, a Group IV-VI semiconductor compound, a Group IV element or compound, and/or a (e.g., any suitable) combination thereof.

Non-limiting examples of a Group II-VI semiconductor compound may include a two-element compound including CdS, CdSe, CdTe, ZnS, ZnSe, ZnTe, ZnO, HgS, HgSe, HgTe, MgSe, and/or MgS, a three-element compound including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS, a four-element compound including CdZnSeS, CdZnSeTe, CdZnSTe, CdHgSeS, CdHgSeTe, CdHgSTe, HgZnSeS, HgZnSeTe, and/or HgZnSTe, and/or the like, and/or a (e.g., any suitable) combination thereof.

Non-limiting examples of a Group III-V semiconductor compound may include a two-element compound including GaN, GaP, GaAs, GaSb, AlN, AlP, AlAs, AlSb, InN, InP, InAs, and/or InSb, a three-element compound including GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or GaAlNP, a four-element compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb, and/or a (e.g., any suitable) combination thereof. A Group III-V semiconductor compound may further include a Group II element. Non-limiting examples of a Group III-V semiconductor compound further including a Group II element may include InZnP, InGaZnP, and/or InAlZnP.

Non-limiting examples of a Group III-VI semiconductor compound may include a two-element compound including GaS, Ga₂S₃, GaSe, Ga₂Se₃, GaTe, InS, InSe, In₂Se₃, and/or InTe, a three-element compound including InGaS₃ and InGaSe₃, and/or a (e.g., any suitable) combination thereof.

Non-limiting examples of a Group I-III-VI semiconductor compound may include a three-element compound including AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂, a four-element compound including AgInGaS₂, AgInGaSe₂, and/or CuInGaS₂, and/or a (e.g., any suitable) combination thereof.

Non-limiting examples of a Group IV-VI semiconductor compound may include a two-element compound including SnS, SnSe, SnTe, PbS, PbSe, and/or PbTe, a three-element compound including SnSeS, SnSeTe, SnSTe, PbSeS, PbSeTe, PbSTe, SnPbS, SnPbSe, and/or SnPbTe, a four-element compound including SnPbSSe, SnPbSeTe, and/or SnPbSTe, and/or a (e.g., any suitable) combination thereof.

The Group IV element or compound may include one of a single-element compound including Si and/or Ge, a two-element compound including SiC and/or SiGe, and/or a (e.g., any suitable) combination thereof.

Each element included in a multi-element compound such as the two-element compound, the three-element compound, and the four-element compound may be present in a particle in a substantially uniform concentration or a non-uniform concentration. For example, the chemical formula above indicates the kind of elements included in the compound, and the element ratio within the compound may be different. For example, AgInGaS₂ may refer to AgInₓGa₁₋ₓS₂ (where x is a real number between 0 and 1).

The quantum dot may have a single structure in which the concentration of each element included in the relevant quantum dot is substantially uniform, or a double structure of a core-shell. For example, a material of the core may be different from a material of the shell.

The shell of a quantum dot may serve as a protective layer that prevents a chemical change of the core to maintain a semiconductor characteristic and/or serve as a charging layer for giving an electrophoretic characteristic to the quantum dot. The shell may include a single layer or a multi-layer. An interface between the core and the shell may have a concentration gradient in which the concentration of an element existing in the shell reduces toward the center.

Examples of the shell of the quantum dot include an oxide of metal or non-metal, a semiconductor compound, and/or a (e.g., any suitable) combination thereof. Non-limiting examples of oxides of metal or non-metal may include a two-element compound including SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, a three-element compound including MgAl₂O₄, CoFe₂O₄, NiFe₂O₄, and/or CoMn₂O₄, and/or a (e.g., any suitable) combination thereof.

Examples of the semiconductor compound may include a III-VI Group semiconductor compound; a II-VI Group semiconductor compound; a III-V Group semiconductor compound; a III-VI Group semiconductor compound; a I-III-VI Group semiconductor compound; a IV-VI Group semiconductor compound; or any combination thereof, as described herein. For example, the semiconductor compound suitable as a shell may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element included in a multi-element compound such as the two-element compound and the three-element compound, may be present in a particle in a substantially uniform concentration or a non-uniform concentration. For example, the chemical formula above indicates the kind of elements included in the compound, and the element ratio within the compound may be different.

A quantum dot may have a full width at half maximum (FWHM) of a light emission spectrum of 45 nm or less, about 40 nm or less, or about 30 nm or less. Within these ranges, color purity or color reproduction of the quantum dot may be improved. In addition, because light emitted from the quantum dot is emitted in all directions, a viewing angle of light may be improved.

In addition, the shape of the quantum dot may be a spherical shape, a pyramid shape, a multi-arm shape, a cubic shape, a nanoparticle, a nanotube, a nanowire, a nanofiber, a nano plate particle, and/or the like.

Because an energy band gap of the quantum dot may be adjusted by adjusting the size of the quantum dot and/or adjusting an element ratio within a quantum dot compound, light in one or more suitable wavelength bands may be obtained from a quantum dot emission layer. Accordingly, a light-emitting element emitting light in one or more suitable wavelengths may be implemented by using the quantum dots (with different sizes and/or different element ratios within quantum dot compound). For example, the size of the quantum dot and/or the element ratio within the quantum dot compounds may be adjusted such that red, green, and/or blue light is emitted. In addition, the quantum dot may be configured such that light in one or more suitable colors is combined to emit white light.

The core of the quantum dot may have a diameter of about 2 nm to about 10 nm. Because, if (e.g., when) exposed to light, the quantum dot may be to emit light in a specific frequency depending on the size of the particle, the kind of the material, and/or the like, an average size of quantum dots included in the first color-converting layer QD1 and an average size of quantum dots included in the second color-converting layer QD2 may be different from each other. For example, as the size of the quantum dots increases, light of a color in a long wavelength may be emitted. Accordingly, the size of the quantum dots may be selected to match the colors of the first pixel Pr and the second pixel Pg.

In addition to the quantum dots, the first and second color-converting layers QD1 and QD2 may further include one or more suitable materials that may mix the quantum dots and properly disperse the quantum dots. For example, the first and second color-converting layers QD1 and QD2 may further include scattering particles, solvents, photoinitiators, binder polymers, dispersants, and/or the like.

The color-converting layer does not correspond to the emission area of the third pixel Pb, and the transmissive layer TL may be arranged on the emission area of the third pixel Pb. The transmissive layer TL may include an organic material that may be to emit or transmit light emitted from the third organic light-emitting element 200B of the third pixel Pb without wavelength conversion. The transmissive layer TL may include scattering particles for uniformly (e.g., substantially uniformly) spreading color. In this case, the scattering particles may have a diameter in a range of about 100 nm to about 400 nm.

In one or more embodiments, the first organic light-emitting element 200R and the second organic light-emitting element 200G included in the first pixel Pr and the second pixel Pg, respectively, may be to emit light of the same wavelength, and colors of the first pixel Pr and the second pixel Pg may be determined as colors of light emitted from the quantum dots of the first color-converting layer QD1 and the quantum dots of the second color-converting layer QD2.

Because the color-converting layer is not provided to correspond to the emission area EA of the third pixel Pb, a color of the third pixel Pb may be determined as a color of light emitted by the third organic light-emitting element 200B. For example, in one or more embodiments, the first pixel Pr may implement red light, the second pixel Pg may implement green light, and the third pixel Pb may implement blue light.

The partition wall 530 may be arranged between the first color-converting layer QD1, the second color-converting layer QD2, and the transmissive layer TL to correspond to the non-emission area NEA. For example, the partition wall 530 may be arranged between the first color-converting layer QD1 and the second color-converting layer QD2, and between the second color-converting layer QD2 and the transmissive layer TL. In one or more embodiments, the partition wall 530 may include an organic material and one or more materials such as Cr or CrOₓ, Cr/CrOₓ, Cr/CrOₓ/CrN_{y}, a resin (carbon pigment, RGB mixed pigment), graphite, a non-Cr-based material as a material for adjusting an optical density. In one or more embodiments, the partition wall 530 may include a pigment that produces a color such as red, green, or yellow. The partition wall 530 may serve as a black matrix for preventing or reducing color mixing and improving visibility.

The first to third color filters 520R, 520G, and 520B, the low refractive layer 540, and the second barrier layer 550 may be arranged between the upper substrate 700 and the first color-converting layer QD1 and the second color-converting layer QD2.

The first to third color filters 520R, 520G, and 520B may be introduced to implement full-color images, improve color purity, and improve outside visibility. The first to third color filters 520R, 520G, and 520B may absorb light passing through the first and second color-converting layers QD1 and QD2 without wavelength conversion by the first and second color-converting layers QD1 and QD2, that is, light whose color is not converted by the quantum dots, and may transmit only light of a desired or suitable wavelength. For example, in one or more embodiments, light passing through the first color filter 520R may be to emit red light, light passing through the second color filter 520G may be to emit green light, and light passing through the third color filter 520B may be to emit blue light.

The low refractive layer 540 may cover the first to third color filters 520R, 520G, and 520B arranged on the upper substrate 700. For example, on the upper substrate 700, the first to third color filters 520R, 520G, and 520B may be separately arranged in a z direction, and the low refractive layer 540 covering the first to third color filters 520R, 520G, and 520B may be arranged. The low refractive layer 540 may include an inorganic material and/or an organic material. For example, the low refractive layer 540 may include a mixed layer of organic and inorganic materials. The low refractive layer 540 may have a lowest refractive index among layers arranged between the first to third color filters 520R, 520G, and 520B and the thin-film encapsulation layer 300, and have, for example, a refractive index of about 1.0 to about 1.3.

Color filters among the first to third color filters 520R, 520G, and 520B may overlap each other in the non-emission area NEA. Because the color filters of different colors overlap each other, a light-blocking rate may be improved.

The second barrier layer 550 may be arranged between the low refractive layer 540 and the first and second color-converting layers QD1 and QD2 and the transmissive layer TL. The second barrier layer 550 may separate the low refractive layer 540, the first and second color-converting layers QD1 and QD2 and the transmissive layer TL from each other and include an inorganic material. For example, the second barrier layer 550 may include silicon nitride, silicon oxynitride, silicon oxide, and/or the like. In one or more embodiments, the second barrier layer 550 may have a refractive index of about 1.4 to about 1.6. A refractive index of the second barrier layer 550 may be less than a refractive index of the first barrier layer 510.

The following is Table 1 showing measurement results of Comparative Examples and some example Embodiments of the present disclosure.

TABLE 1

| | | | | Light efficiency of | | | |
|---|---|---|---|---|---|---|---|
| | | | | blue light | | Room | |
| | | | | [ref. Contrast | | temperature | |
| Experimental | | | Driving | increase/decrease | | lifetime | |
| Example | EIL | Cathode | voltage (V) | rate, Δ] | | (brightness 80%) | |
| Comparative | Yb 15 Å | Ag:Mg 100 Å | 17.0 | 125.8 | [ref.] | 150 | hr |
| Example 1 | | (Mg 0.82 wt %) | | | | | |
| Comparative | not | Ag:Mg 100 Å | 17.5 | 115 | [Δ−9%] | 75 | hr |
| Example 2 | present | (Mg 0.82 wt %) | | | | | |
| Comparative | | Ag:Li 100 Å | 17.5 | 113 | [Δ−10%] | 40 | hr |
| Example 3 | | (Li 0.3 wt % or 7 | | | | | |
| | | vol %) | | | | | |
| Embodiment 1 | | Ag:Li 100 Å | 17.0 | 133.1 | [Δ+6%] | 151 | hr |
| | | (Li 0.5 wt % or | | | | | |
| | | 10 vol %) | | | | | |
| Embodiment 2 | | Ag:Li 100 Å | 16.9 | 140.4 | [Δ+12%] | 151 | hr |
| | | (Li 1 wt % or 20 | | | | | |
| | | vol %) | | | | | |
| Embodiment 3 | | Ag:Li 100 Å | 16.8 | 134.5 | [Δ+7%] | 150 | hr |
| | | (Li 1.5 wt % or | | | | | |
| | | 30 vol %) | | | | | |
| Comparative | | Ag:Li 100 Å | 16.7 | 123.2 | [Δ−1%] | 155 | hr |
| Example 4 | | (Li 2 wt % or 40 | | | | | |
| | | vol %) | | | | | |

Table 1 shows electrical characteristics, light efficiency, and environment reliability (e.g., room temperature lifetime) as characteristics of embodiments and comparative examples.

Embodiment 1 to Embodiment 3 show results for an organic light-emitting element not having an EIL and having a second electrode including about 0.5 wt % to about 1.5 wt % based on a total weight of 100 wt % of the second electrode (or about 10 vol % to about 30 vol % based on a total volume of 100 vol % of the second electrode) of Li as an alkali metal. In addition, Comparative Example 1 shows results for an organic light-emitting element including an EIL and a second electrode (that is, Ag:Mg), Comparative Example 2 shows results for an organic light-emitting element not including an EIL and including a second electrode (that is, Ag:Mg), and Comparative Examples 3 and 4 show results for an organic light-emitting element not including an EIL and including a second electrode that includes less than 0.5 wt % or greater than 1.5 wt % of Li as an alkali metal.

First, Comparative Example 1 is about an organic light-emitting element

including ytterbium (Yb) as an EIL with a thickness of about 15 Å and a second electrode (that is, Ag:Mg) on the EIL, showing an organic light-emitting element structure according to the related art.

Compared to this, Comparative Example 2 is about a structure having the same second electrode as that of Comparative Example 1 and without an EIL. In Comparative Example 2, a driving voltage increased, a light efficiency deteriorated by about −9%, and a room temperature life was significantly reduced compared to Comparative Example 1.

In addition, Comparative Example 3 is about a structure without an EIL and including a second electrode (that is, Ag:Li, Li 0.3 wt %). Because Li content (e.g., amount) departs from the spirit of the disclosure, consequently, it is confirmed that a driving voltage increased, a light efficiency deteriorated by about −10%, and a room temperature life was remarkably reduced.

In addition, Comparative Example 4 is about a structure without an EIL and including a second electrode (that is, Ag:Li, Li 2 wt %). Li content (e.g., amount) exceeds the spirit of the disclosure. Comparative Example 4 shows improved results in an aspect of a driving voltage but reduced light efficiency of about −1%. Consequently, it is shown that the quality mildly deteriorated compared to Comparative Example 1.

Embodiment 1 to Embodiment 3 are about structures without an EIL and including second electrodes with Ag:Li (Li 0.5 wt %), Ag:Li (Li 1.0 wt %), and Ag:Li (Li 1.5 wt %), respectively. Li content (e.g., amount) falls within the spirit of the disclosure. Consequently, it is confirmed that a driving voltage was reduced, a light efficiency increased by about 6% to about 12%, and a room temperature life was the same or increased.

According to the above results, it is confirmed that, because the organic light-emitting element according to one or more embodiments of the present disclosure allows the second electrode to include the conductive material and a preset ratio of alkali metal together, the characteristics of the organic light-emitting element may be improved even without an EIL.

The following is Table 2 showing thickness effect results of example Embodiments according to present disclosure. In Table 2, efficiency of the element was measured by including the same Li content (e.g., amount) of about 1 wt % and varying the thickness of the second electrode.

TABLE 2

| | | | | Light efficiency of | |
|---|---|---|---|---|---|
| | | | | blue light | Room |
| | | | | [ref. Contrast | temperature |
| Experimental | | | Driving | increase/decrease | lifetime |
| Example | EIL | Cathode | voltage (V) | rate, Δ] | (brightness 80%) |
| Embodiment 5 | not | Ag:Li 100 Å | 16.9 | 140.4 [Δ+12%] | 151 hr |
| | present | (Li 1 wt %) | | | |
| Embodiment 6 | | Ag:Li 125 Å | 16.9 | 148.8 [Δ+18%] | 158 hr |
| | | (Li 1 wt %) | | | |
| Embodiment 7 | | Ag:Li 150 Å | 16.9 | 144.2 [Δ+15%] | 161 hr |
| | | (Li 1 wt %) | | | |
| Embodiment 8 | | Ag:Li 200 Å | 16.9 | 131.4 [Δ+4%] | 160 hr |
| | | (Li 1 wt %) | | | |

Referring to Table 2, like Embodiment 5 to Embodiment 8, in embodiments in which the thickness of the second electrode satisfies the range of about 50 Å to about 200 Å, which is within the spirit of the disclosure, it may be confirmed that a driving voltage was improved, a room temperature lifetime increased, and a light efficiency increased significantly from about 4% to about 18%, compared to the Comparative Example 1.

The following is Table 3 showing measurement results of examples according to one or more embodiments of the present disclosure.

TABLE 3

| | | | | | | | W efficiency |
|---|---|---|---|---|---|---|---|
| | | | | | | | [ref. Contrast |
| Experimental | | | Driving | R-QD | G-QD | B | increase/ |
| example | EIL | Cathode | voltage | efficiency | efficiency | efficiency | decrease rate, Δ] |
| Experimental | Yb 10 Å | Ag:Mg | 17.2 | 16.0 | 69.5 | 125.9 | 25.7 |
| Example A | | (Mg 0.82 | | | | | [ref.] |
| | | wt %) | | | | | |
| Experimental | not | Ag:Li | 17.0 | 18.7 | 78.8 | 139.4 | 29.1 |
| Example B | present | (Li 1 | | | | | [Δ + 13.2%] |
| | | wt %) | | | | | |

| | | | |
|---|---|---|---|
| Experimental | Ag:Mg | 17.5 | Measurement not possible due to |
| Example C | (Mg 0.82 | | component deterioration |
| | wt %) | | |

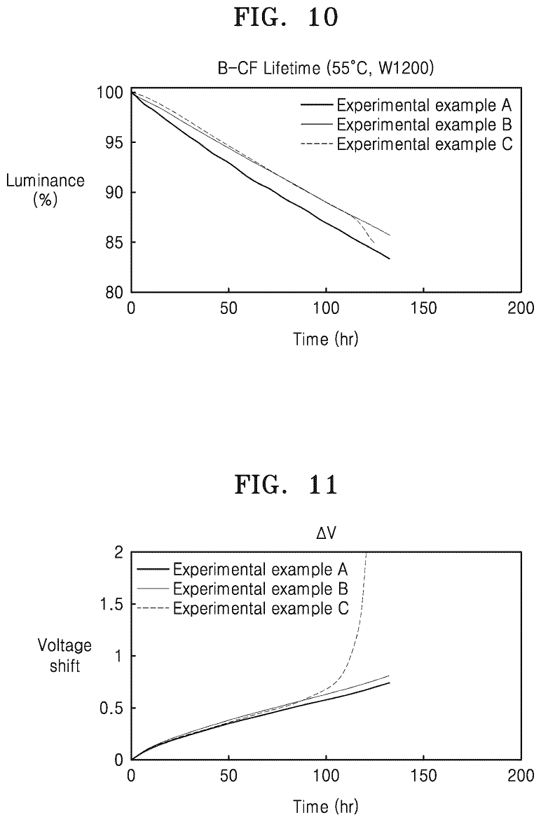

FIG. 10 and FIG. 11 are graphs showing an amount of change in an element life of blue light and an amount of change in a driving voltage, respectively, of examples in Table 3.

Referring to Table 3, Experimental Example A, Experimental Example B, and Experimental Example C are examples studied with an organic light-emitting element having a tandem structure in which five emission layers are stacked. The five emission layers were studied in a structure of blue/blue/green/blue/green. Experimental Example A is a Comparative Example and is about an organic light-emitting element including ytterbium (Yb) as an EIL with a thickness of about 10 Å and a second electrode (that is, Ag:Mg) on the EIL, showing an organic light-emitting element structure according to the related art.

Experimental Example C is a Comparative Example and is about a structure without an EIL and including a second electrode (that is, Ag:Mg), showing a state in which a driving voltage increased and measurement of a light efficiency is impossible due to element deterioration. For example, Experimental Example C, having the same second electrode configuration as Experimental Example A, shows the characteristics of the organic light-emitting element was greatly deteriorated in the case where the EIL is simply removed.

In contrast, in Experimental Example B, although the EIL was removed, because Li content (e.g., amount) within the second electrode (that is, Ag:Li, Li 1.0 wt %) satisfies the range according to the spirit of the disclosure, the driving voltage is reduced and a light efficiency of each of red (R), green (G), and blue (B) increased. As confirmed through this, in the organic light-emitting element according to one or more embodiments, the structure of the organic light-emitting element is simplified by removing the EIL, dependency on rare earth metal is reduced, and concurrently (e.g., simultaneously), an increase in the element characteristics may be derived and achieved.

FIG. 10 is a graph measuring life of elements each emitting blue light. The relevant experiment was performed under atmosphere of 55° C. and 1200 (unit NIT) of white light. Referring to the graph of FIG. 10, compared to Experimental Example B, which is an embodiment of the present disclosure, an element life of blue light in each of Experimental Example A and Experimental Example C was reduced more quickly.

In addition, referring to the graph of FIG. 11, in Experimental Example C in which only an EIL is removed, an amount of change in a driving voltage rapidly increased after about 100 hours, and electrical characteristics significantly deteriorated. In contrast, in Experimental Example B, which is an embodiment of the present disclosure, it may be confirmed that, although the EIL was removed, Experimental Example B shows an amount of change in the driving voltage of an almost similar level to Experimental Example A including the EIL.

The following is Table 4 showing measurement results of Comparative Examples and some example Embodiments of the present disclosure.

TABLE 4

| | | | | Light efficiency | | | |
|---|---|---|---|---|---|---|---|
| | | | | of blue light | | Room | |
| | | | | [ref. Contrast | | temperature | |
| Experimental | | | Driving | increase/decrease | | lifetime | |
| example | EIL | Cathode | voltage (V) | rate, Δ] | | (brightness 80%) | |
| Comparative | Yb 15 Å | Ag:Mg 100 Å | 17.0 | 125.8 | [ref.] | 150 | hr |
| Example 1 | | (Mg 0.82 | | | | | |
| | | wt %) | | | | | |
| Comparative | not | Ag:Mg 100 Å | 17.5 | 115 | [Δ−9%] | 75 | hr |
| Example 2 | present | (Mg 0.82 | | | | | |
| | | wt %) | | | | | |
| Comparative | | Ag:Na 100 Å | 17.2 | 122 | [Δ−3%] | 102 | hr |
| Example 5 | | (Na 0.1 wt % | | | | | |
| | | or 1 vol %) | | | | | |
| Embodiment | | Ag:Na 100 Å | 16.5 | 148.1 | [Δ+18%] | 155 | hr |
| 9 | | (Na 0.27 | | | | | |
| | | wt % or 3 | | | | | |
| | | vol %) | | | | | |
| Embodiment | | Ag:Na 100 Å | 16.3 | 150.4 | [Δ+20%] | 160 | hr |
| 10 | | (Na 0.91 | | | | | |
| | | wt % or 10 | | | | | |
| | | vol %) | | | | | |
| Embodiment | | Ag:Na 100 Å | 16.5 | 143.5 | [Δ+14%] | 162 | hr |
| 11 | | (Na 1.8 wt % | | | | | |
| | | or 20 vol %) | | | | | |
| Embodiment | | Ag:Na 100 Å | 16.8 | 135.2 | [Δ+7%] | 151 | hr |
| 12 | | (Na 2.69 | | | | | |
| | | wt % or 30 | | | | | |
| | | vol %) | | | | | |

Table 4 is a table showing electrical characteristics, a light efficiency, and environment reliability (e.g., room temperature lifetime) as characteristics of embodiments and comparative examples.

Embodiment 9 to Embodiment 12 show results for the organic light-emitting element not including an EIL and including the second electrode including, as an alkali metal, Na in the range of about 0.27 wt % to about 2.69 wt % based on a total weight of 100 wt % of the second electrode, which is within the spirit of the disclosure, according to one or more embodiments.

In addition, Comparative Example 1 (see Table 4 or Table 1) shows results for an organic light-emitting element including an EIL and a second electrode (that is, Ag:Mg), Comparative Example 2 (see Table 4 or Table 1) shows results for an organic light-emitting element not including an EIL and a second electrode (that is, Ag:Mg), and Comparative Example 5 shows results for an organic light-emitting element not including an EIL and a second electrode including less than 0.27 wt % of Na as an alkali metal.

First, Comparative Example 1 is about an organic light-emitting element including ytterbium (Yb) as an EIL with a thickness of about 15 Å and a second electrode (that is, Ag:Mg) on the EIL, showing an organic light-emitting element structure according to the related art.

Compared to this, Comparative Example 2 is about a structure having the same second electrode as that of Comparative Example 1 and without an EIL. In Comparative Example 2, a driving voltage increased, a light efficiency deteriorated by about −9%, and a room temperature life was significantly reduced compared to Comparative Example 1.

In addition, Comparative Example 5 is about a structure without an EIL and including a second electrode (that is, Ag:Na, Na 0.1 wt %). Because Na content (e.g., amount) departs from the spirit of the disclosure, consequently, it is shown that a driving voltage increased, a light efficiency deteriorated by about −3%, and a room temperature life was reduced.

In contrast, Embodiment 9 to Embodiment 12 are about structures without an EIL and including Ag:Na (Na 0.27 wt %), Ag:Na (Na 0.91 wt %), Ag:Na (Na 1.8 wt %), and Ag:Na (Na 2.69 wt %) as second electrodes, respectively. Because Na content (e.g., amount) is included in the spirit of the disclosure, consequently, it is confirmed that a driving voltage was reduced, a light efficiency greatly increased by about 7% to about 20%, and a room temperature life increased.

According to the above results, it is confirmed that, because the organic light-emitting element according to one or more embodiments allows the second electrode to include the conductive material and a preset ratio of an alkali metal together, the characteristics of the organic light-emitting element may be equally or more improved even without an EIL.

The following is Table 5 showing thickness effect results of example Embodiments according to present disclosure.

In Table 5, efficiency of the element was measured by including the same Na content (e.g., amount) of about 0.91 wt % and varying the thickness of the second electrode.

TABLE 5

| | | | | Light efficiency of | | Room |
|---|---|---|---|---|---|---|
| | | | | blue light | | temperature |
| Experimental | | | Driving | (increase/decrease | | lifetime |
| Example | EIL | Cathode | voltage (V) | rate Δ) | | (brightness 80%) |
| Embodiment | not present | Ag:Na 100 Å | 16.3 | 150.4 | (+20%) | 160 hr |
| 13 | | (Na 0.91 wt %) | | | | |
| Embodiment | | Ag:Na 125 Å | 16.3 | 155.7 | (+24%) | 165 hr |
| 14 | | (Na 0.91 wt %) | | | | |
| Embodiment | | Ag:Na 150 Å | 16.3 | 153 | (+22%) | 162 hr |
| 15 | | (Na 0.91 wt %) | | | | |
| Embodiment | | Ag:Na 200 Å | 16.3 | 143.4 | (+14%) | 167 hr |
| 16 | | (Na 0.91 wt %) | | | | |

Referring to Table 5, like Embodiment 13 to Embodiment 16, in embodiments in which the thickness of the second electrode satisfies the range of about 50 Å to about 200 Å, which is within the spirit of the disclosure, it may be confirmed that a driving voltage was improved, a room temperature life increased, and a light efficiency increased significantly from about 14% to about 24%.

The display apparatus according to one or more embodiments is applicable to one or more suitable electronic apparatuses. An electronic apparatus according to one or more embodiments may include the display apparatus and may further include a module or device having other additional functions in addition to the display apparatus.

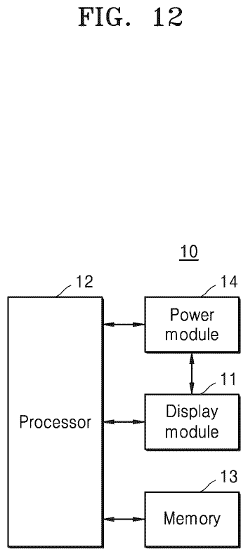

FIG. 12 is a block diagram of an electronic apparatus according to one or more embodiments of the present disclosure. Referring to FIG. 12, an electronic apparatus 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information desired or required for operations of the processor 12 and/or the display module 11. When the processor 12 executes an application stored in the memory 13, image data signals and/or input control signals are transferred to the display module 11, and the display module 11 may process the received signals and output image information through a display screen.

The power module 14 may include a power supply module such as a power adapter and/or a battery device, and a power converting module converting power supplied by the power supply module and generating power desired or required for operations of the electronic apparatus 10.

At least one of (e.g., at least one selected from among) the elements of the electronic apparatus 10 may be included in the display apparatus according to the above-described embodiments. In addition, some of individual modules functionally included within one module may be included within the display apparatus, and others may be provided separately from the display apparatus. For example, the display apparatus may include the display module 11, and the processor 12, the memory 13, and the power module 14 may be provided in the form of a different device within the electronic apparatus 10.

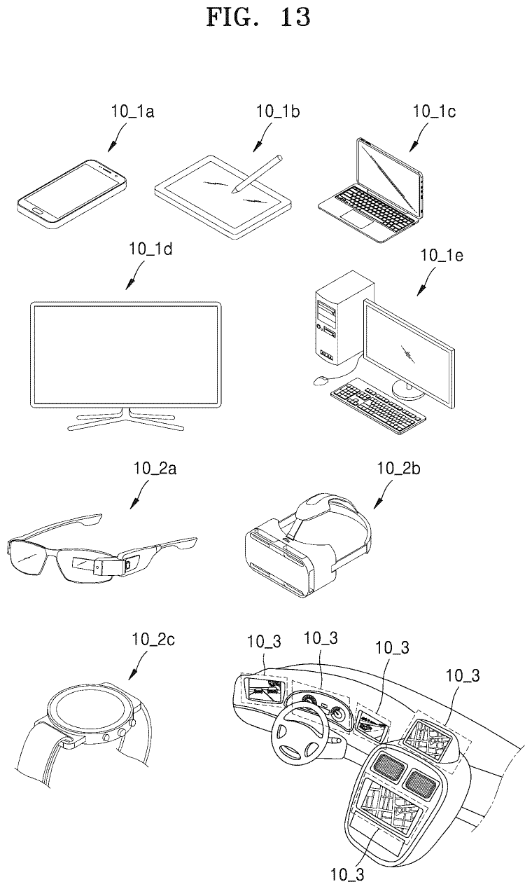

FIG. 13 is a schematic view of electronic apparatuses according to one or more embodiments of the present disclosure.

Referring to FIG. 13, one or more suitable electronic apparatuses employing the display apparatus according to one or more embodiments may include not only an electronic apparatus for displaying images, such as a smartphone 10_1a, a tablet personal computer (PC) 10_1b, a lap-top computer 10_1c, a TV 10_1d, and a desk monitor 10_1e, but also a wearable electronic apparatus including a display module, such as a smart glasses 10_2a, a head-mount display 10_2b, and a smartwatch 10_2c, and a vehicle electronic apparatus 10_3 including a display module, such as an instrument panel of an automobile, a center information display (CID) arranged on a center facia and a dashboard, and a room mirror display.

Although only the organic light-emitting element and the display apparatus including the same are mainly described, the disclosure is not limited thereto. For example, a method of manufacturing the organic light-emitting element and the display apparatus also falls within the scope of the disclosure.

According to one or more embodiments, an organic light-emitting element with a simplified structure and an improved efficiency, and a display apparatus including the same may be implemented. However, the scope of the disclosure is not limited thereto.

In the context of the present application and unless otherwise defined, the terms “use,” “using,” and “used” may be considered synonymous with the terms “utilize,” “utilizing,” and “utilized,” respectively.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” or “on” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” “approximately” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light-emitting element, the display module, the display device/apparatus, the electronic device/apparatus, the display device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. An organic light-emitting element comprising:
a first electrode;
a hole injection layer on the first electrode;
a hole transport layer on the hole injection layer;
an emission layer on the hole transport layer, the emission layer comprising an organic material;
an electron transport layer on the emission layer; and
a second electrode directly on the electron transport layer,
wherein the second electrode comprises a conductive material other than alkali metal and about 3 vol % to about 30 vol % of an alkali metal based on a total volume of 100 vol % of the second electrode.

2. The organic light-emitting element of claim 1, wherein the alkali metal of the second electrode comprises about 0.5 wt % to about 1.5 wt % of lithium based on a total weight of 100 wt % of the second electrode.

3. The organic light-emitting element of claim 1, wherein the alkali metal of the second electrode comprises about 0.27 wt % to about 2.69 wt % of sodium based on a total weight of 100 wt % of the second electrode.

4. The organic light-emitting element of claim 1, wherein a thickness of the second electrode is about 50 Å to about 200 Å.

5. The organic light-emitting element of claim 1, wherein a work function of the alkali metal of the second electrode is about 2.3 eV to about 2.9 eV.

6. The organic light-emitting element of claim 1, wherein a light absorption rate k of the alkali metal of the second electrode is about 1.79 to about 2.03 with respect to light having a wavelength of about 450 nm.

7. The organic light-emitting element of claim 1, wherein the emission layer comprises a stack of two or more layers.

8. The organic light-emitting element of claim 1, wherein a proportion of the alkali metal within the second electrode gradually increases in a direction away from a central portion of a cross-section of the second electrode.

9. A display apparatus comprising:
a substrate;
a circuit layer on the substrate and comprising a unit circuit and an insulating layer, the unit circuit comprising a thin-film transistor and a storage capacitor;
an organic light-emitting element on the circuit layer and electrically connected to the unit circuit; and
an encapsulation layer on the organic light-emitting element and sealing the organic light-emitting element,
wherein the organic light-emitting element comprises a first electrode, a hole injection layer on the first electrode, a hole transport layer on the hole injection layer, an emission layer on the hole transport layer and comprising an organic material, an electron transport layer on the emission layer, and a second electrode directly on the electron transport layer and comprising a conductive material other than alkali metal and about 3 vol % to about 30 vol % of an alkali metal based on a total volume of 100 vol % of the second electrode.

10. The display apparatus of claim 9, wherein the alkali metal of the second electrode comprises about 0.5 wt % to about 1.5 wt % of lithium based on a total weight of 100 wt % of the second electrode.

11. The display apparatus of claim 9, wherein the alkali metal of the second electrode comprises about 0.27 wt % to about 2.69 wt % of sodium based on a total weight of 100 wt % of the second electrode.

12. The display apparatus of claim 9, wherein a thickness of the second electrode is about 50 Å to about 200 Å.

13. The display apparatus of claim 9, wherein a work function of the alkali metal of the second electrode is about 2.3 eV to about 2.9 eV.

14. The display apparatus of claim 9, wherein the emission layer comprises two or more layers.

15. The display apparatus of claim 9, wherein a proportion of the alkali metal within the second electrode gradually increases from a central portion of a cross-section of the second electrode toward the electron transport layer.

16. The display apparatus of claim 9, wherein the substrate comprises a display area and a peripheral area outside the display area,
the organic light-emitting element is provided in plurality in the display area,
the second electrode is integral with respect to the plurality of organic light-emitting elements over an entire surface of the display area, and
a proportion of the alkali metal within the second electrode is lowest in a portion of the second electrode corresponding to a central portion of the display area, and increases toward a portion of the second electrode corresponding to an edge of the display area.

17. The display apparatus of claim 9, wherein the substrate comprises a display area and a peripheral area outside the display area,
the organic light-emitting element comprises a first organic light-emitting element in a central portion of the display area, and a second organic light-emitting element in proximity to an edge of the display area,
the second electrode is integrally arranged over the first organic light-emitting element and the second organic light-emitting element and comprises a first portion in the first organic light-emitting element and a second portion in the second organic light-emitting element, and
in the first organic light-emitting element, a proportion of the alkali metal within the first portion of the second electrode gradually increases in a direction away from a central portion of a cross-section of the first portion of the second electrode, and
in the second organic light-emitting element, a proportion of the alkali metal within the second portion of the second electrode is constant.

18. An electronic apparatus comprising a processor and a display apparatus controlled by the processor, wherein the display apparatus comprises:
a substrate;
a circuit layer on the substrate and comprising a unit circuit and an insulating layer, the unit circuit comprising a thin-film transistor and a storage capacitor;
an organic light-emitting element on the circuit layer and electrically connected to the unit circuit; and
an encapsulation layer on the organic light-emitting element and sealing the organic light-emitting element,
wherein the organic light-emitting element comprises a first electrode, a hole injection layer on the first electrode, a hole transport layer on the hole injection layer, an emission layer on the hole transport layer and comprising an organic material, an electron transport layer on the emission layer, and a second electrode directly on the electron transport layer and comprising a conductive material other than alkali metal and about 3 vol % to about 30 vol % of an alkali metal based on a total volume of 100 vol % of the second electrode.

19. The electronic apparatus of claim 18, wherein the alkali metal of the second electrode comprises about 0.5 wt % to about 1.5 wt % of lithium based on a total weight of 100 wt % of the second electrode.

20. The electronic apparatus of claim 18, wherein the alkali metal of the second electrode comprises about 0.27 wt % to about 2.69 wt % of sodium based on a total weight of 100 wt % of the second electrode.
